(19) United States
(12) Patent Application Publication
(10) Pub. No.: US 2026/0371605 A1
(43) Pub. Date: Nov. 19, 2026

(54) VIA LINER FOR A CONDUCTIVE VIA STRUCTURE AND METHODS FOR FORMING THE SAME

(71) Applicant: Taiwan Semiconductor Manufacturing Company Limited, Hsinchu (TW)

(72) Inventors: Ching Ju Yang, Hsinchu (TW); Hai-Dang Trinh, Hsinchu (TW); Yao-Wen Chang, Taipei (TW)

(21) Appl. No.: 19/207,726

(22) Filed: May 14, 2025

(51) Int. Cl. H10B 61/00

(52) U.S. Cl. CPC H10B 61/10

(57) ABSTRACT

A device structure may be provided by: forming a first metal interconnect structure in a lower-level dielectric material layer over a substrate; depositing a cobalt-containing metal barrier liner on the first metal interconnect structure; depositing a via-level dielectric layer over the lower-level dielectric material layer prior to, or after, formation of the cobalt-containing metal barrier liner; forming a via cavity through the via-level dielectric layer; and forming a metal via fill structure over the cobalt-containing metal barrier liner within the via cavity.

### BACKGROUND

Within advanced semiconductor devices, the continued scaling of interconnect structures presents challenges related to electromigration, increased contact resistance, and metal diffusion into adjacent dielectric layers. As via dimensions decrease, barrier materials such as tantalum nitride (TaN) and titanium nitride (TiN) exhibit high resistivity and limited scalability, leading to increased resistance-capacitance (RC) delay and degraded signal integrity. Additionally, copper diffusion through dielectric materials remains a reliability concern, necessitating an effective diffusion barrier that mitigates against metal migration while maintaining low electrical resistance. Existing solutions for via barrier liners fail to simultaneously provide low resistance, strong adhesion, and electromigration resistance, resulting in device performance degradation and reduced interconnect reliability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an exemplary structure after formation of complementary metal-oxide-semiconductor (CMOS) transistors and lower-level metal interconnect structures embedded in lower-level dielectric material layers according to an embodiment of the present disclosure.

FIG. 2A-2F are sequential vertical cross-sectional views of a region of the exemplary structure during formation of a metallic via structure having a first configuration according to an embodiment of the present disclosure.

FIG. 3A-3E are sequential vertical cross-sectional views of a region of the exemplary structure during formation of a metallic via structure having a second configuration according to an embodiment of the present disclosure.

FIG. 4A-4F are sequential vertical cross-sectional views of a region of the exemplary structure during formation of a metallic via structure having a third configuration according to an embodiment of the present disclosure.

FIGS. 5A and 5B are sequential vertical cross-sectional views of a region of the exemplary structure during formation of a metallic via structure having a fourth configuration according to an embodiment of the present disclosure.

FIG. 6 is a vertical cross-sectional view of the exemplary structure after formation of an array of metallic via structures according to an embodiment of the present disclosure.

FIG. 7 is a vertical cross-sectional view of the exemplary structure after formation of a bottom electrode material layer, a memory material layer stack, and a top electrode material layer according to an embodiment of the present disclosure.

FIG. 8 is a vertical cross-sectional view of the exemplary structure after patterning the top electrode material layer into top electrodes according to an embodiment of the present disclosure.

FIG. 9 is a vertical cross-sectional view of the exemplary structure after a focused ion beam etch process that forms an array of memory cells according to an embodiment of the present disclosure.

FIG. 10 is a vertical cross-sectional view of the exemplary structure after formation of an array of dielectric spacers according to an embodiment of the present disclosure.

FIG. 11 is a vertical cross-sectional view of the exemplary structure after formation of a memory-level dielectric layer according to an embodiment of the present disclosure.

FIG. 12 is a vertical cross-sectional view of the exemplary structure after formation of integrated line and via cavities through the memory-level dielectric layer according to an embodiment of the present disclosure.

FIG. 13 is a vertical cross-sectional view of the exemplary structure after formation of memory-level metal interconnect structures according to an embodiment of the present disclosure.

FIG. 14 is a first flowchart that illustrates a first sequence of processing steps for manufacturing a device structure of the present disclosure.

FIG. 15 is a second flowchart that illustrates a second sequence of processing steps for manufacturing a device structure of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. A first physical element is “embedded” with a second physical element if the entire volume of the first element is located within a hypothetical volume defined by a set of hypothetical surfaces having the least total surface area among all sets of hypothetical surfaces containing the entirety of the outer surfaces of the second element and topologically homeomorphic to a spherical surface. Such a set of hypothetical surfaces covers each opening, if present, in the outer surfaces with a minimum-area surface segment among all possible opening-free surface segments. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Unless explicitly stated otherwise, each material portion is presumed to have a homogeneous material composition throughout.

As used herein, removal of a first material is “selective to” a second material if the removal rate of the first material is greater than the removal rate of the second material at least by a factor of 3. Unless otherwise expressly indicated, removal of the first material selectively to the second material implies the possibility of the ratio of the removal rates equal to, or greater than, 3.0, and/or 10, and/or 100, and/or 1,000. As used herein, a first surface and a second surface are “vertically coincident” with each other if the second surface overlies or underlies the first surface and there exists a vertical plane or a substantially vertical plane that includes the first surface and the second surface. A vertical plane is a two-dimensional manifold containing a contiguous set of an uncountable infinity of vertical lines, and has a uniform one-dimensional horizontal cross-sectional shape that is invariant under translation along a vertical direction. The vertical plane may be a Euclidian plane if the uniform one-dimensional horizontal cross-sectional shape is a line, or may be a non-Euclidian plane if the uniform one-dimensional shape is not a line. A substantially vertical line is a straight line that deviates from a vertical direction by an angle less than 5 degrees. A substantially vertical plane is a two-dimensional manifold containing a contiguous set of an uncountable infinity of substantially vertical lines and/or vertical lines.

To address the high resistance, poor adhesion, and limited scalability of via liners in metal interconnect structures, embodiments of the present disclosure provide a cobalt-containing metal barrier liner that is formed on an exposed top surface of a metal interconnect structure. The cobalt-containing metal barrier liner provides lower resistance, stronger adhesion, and enhanced electromigration resistance compared to traditional barrier materials. In one embodiment, the cobalt-containing metal barrier liner consists of an alternating stack of cobalt layers and tungsten layers, forming a multilayer diffusion barrier that enhances conductivity while mitigating against copper diffusion. In another embodiment, the barrier liner consists entirely of cobalt, deposited via atomic layer deposition or chemical vapor deposition. The via cavity is then filled with a metal, such as tungsten, using a selective deposition process that nucleates only on metallic surfaces while suppressing growth on dielectric surfaces. This ensures void-free via formation, enhances interconnect reliability, and reduces overall resistance-capacitance delay. The disclosed cobalt-containing metal barrier liner provides a scalable, low-resistance solution for advanced semiconductor interconnects, enabling improved device performance and long-term reliability. The various aspects of the present disclosure are now described with reference to accompanying drawings.

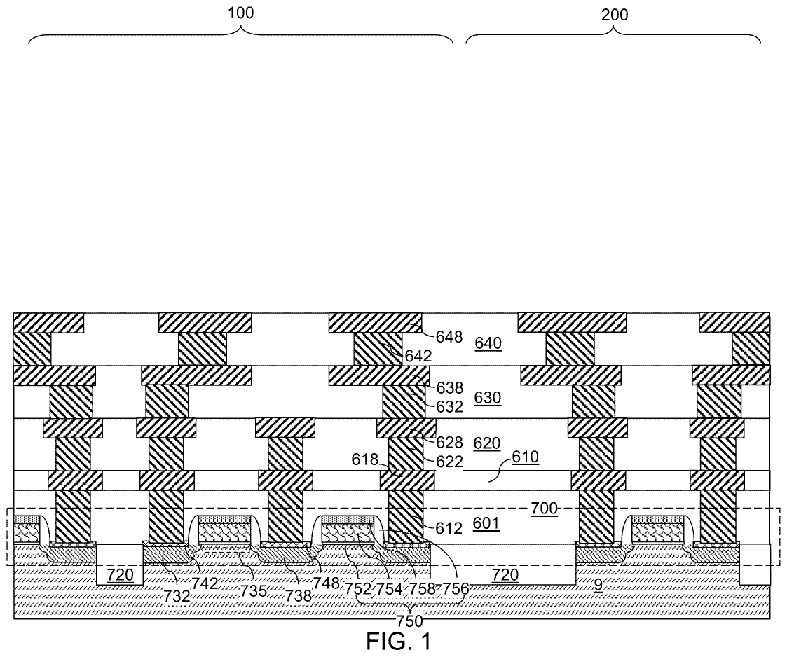

FIG. 1 is a vertical cross-sectional view of an exemplary structure after formation of complementary metal-oxide-semiconductor (CMOS) transistors, metal interconnect structures embedded in dielectric material layers, and a via-level dielectric layer according to an embodiment of the present disclosure. The exemplary structure includes complementary metal-oxide-semiconductor (CMOS) transistors and metal interconnect structures formed in dielectric material layers. Specifically, the exemplary structure includes a substrate 9, which may be a semiconductor substrate such as a commercially available silicon wafer. Shallow trench isolation structures 720 including a dielectric material such as silicon oxide may be formed in an upper portion of the substrate 9. Suitable doped semiconductor wells, such as p-type wells and n-type wells, may be formed within each area that may be laterally enclosed by a portion of the shallow trench isolation structures 720. Field effect transistors may be formed over the top surface of the substrate 9. For example, each field effect transistor may include a source region 732, a drain region 738, a semiconductor channel 735 that includes a surface portion of the substrate 9 extending between the source region 732 and the drain region 738, and a gate structure 750. Each gate structure 750 may include a gate dielectric 752, a gate electrode 754, a gate cap dielectric 758, and a dielectric gate spacer 756. A source-side metal-semiconductor alloy region 742 may be formed on each source region 732, and a drain-side metal-semiconductor alloy region 748 may be formed on each drain region 738. While planar field effect transistors are illustrated in the drawings, embodiments are expressly contemplated herein in which the field effect transistors may additionally or alternatively include fin field effect transistors (FinFET), gate-all-around field effect transistors (GAAFETs), or any other type of field effect transistors (FETs).

The exemplary structure may include a memory array region 100 in which an array of memory elements may be subsequently formed, and a peripheral region 200 in which logic devices that support operation of the array of memory elements may be formed. In one embodiment, devices (such as field effect transistors) in the memory array region 100 may include bottom electrode access transistors that provide access to bottom electrodes of memory cells to be subsequently formed. Top electrode access transistors that provide access to top electrodes of memory cells to be subsequently formed may be formed in the peripheral region 200 at this processing step. Devices (such as field effect transistors) in the peripheral region 200 may provide functions that may be needed to operate the array of memory cells to be subsequently formed. Specifically, devices in the peripheral region may be configured to control the programming operation, the erase operation, and the sensing (read) operation of the array of memory cells. For example, the devices in the peripheral region may include a sensing circuitry and/or a top electrode bias circuitry. The devices formed on the top surface of the substrate 9 may include complementary metal-oxide-semiconductor (CMOS) transistors and optionally additional semiconductor devices (such as resistors, diodes, capacitors, etc.), and are collectively referred to as CMOS circuitry 700.

Various metal interconnect structures formed within dielectric material layers may be subsequently formed over the substrate 9 and the devices (such as field effect transistors). The dielectric material layers may include, for example, a contact-level dielectric material layer 601, a first metal-line-level dielectric material layer 610, a second line-and-via-level dielectric material layer 620, a third line-and-via-level dielectric material layer 630, and a fourth line-and-via-level dielectric material layer 640. The metal interconnect structures may include device contact via structures 612 formed in the contact-level dielectric material layer 601 and contact a respective component of the CMOS circuitry 700, first metal line structures 618 formed in the first metal-line-level dielectric material layer 610, first metal via structures 622 formed in a lower portion of the second line-and-via-level dielectric material layer 620, second metal line structures 628 formed in an upper portion of the second line-and-via-level dielectric material layer 620, second metal via structures 632 formed in a lower portion of the third line-and-via-level dielectric material layer 630, third metal line structures 638 formed in an upper portion of the third line-and-via-level dielectric material layer 630, third metal via structures 642 formed in a lower portion of the fourth line-and-via-level dielectric material layer 640, and fourth metal line structures 648 formed in an upper portion of the fourth line-and-via-level dielectric material layer 640. In one embodiment, the second metal line structures 628 may include source lines that are connected to a source-side power supply for an array of memory elements. The voltage provided by the source lines may be applied to the bottom electrodes through the access transistors provided in the memory array region 100.

Each of the dielectric material layers (601, 610, 620, 630, 640) may include a dielectric material such as undoped silicate glass, a doped silicate glass, organosilicate glass, amorphous fluorinated carbon, porous variants thereof, or combinations thereof. Each of the metal interconnect structures (612, 618, 622, 628, 632, 638, 642, 648) may include at least one conductive material, which may be a combination of a metallic liner layer (such as a metallic nitride or a metallic carbide) and a metallic fill material. Each metallic liner layer may include TiN, TaN, WN, TiC, TaC, and WC, and each metallic fill material portion may include W, Cu, Al, Co, Ru, Mo, Ta, Ti, alloys thereof, and/or combinations thereof. Other suitable materials within the contemplated scope of disclosure may also be used. In one embodiment, the first metal via structures 622 and the second metal line structures 628 may be formed as integrated line and via structures by a dual damascene process, the second metal via structures 632 and the third metal line structures 638 may be formed as integrated line and via structures, and/or the third metal via structures 642 and the fourth metal line structures 648 may be formed as integrated line and via structures. While the present disclosure is described using an embodiment in which an array of memory cells formed over the fourth line-and-via-level dielectric material layer 640, embodiments are expressly contemplated herein in which the array of memory cells may be formed at a different metal interconnect level.

The dielectric material layers (601, 610, 620, 630, 640) may be located at a lower level relative to an array of memory cells to be subsequently formed. As such, the dielectric material layers (601, 610, 620, 630, 640) are herein referred to as lower-level dielectric layers, i.e., dielectric material layer located at a lower level relative to the array of memory cells to be subsequently formed. The metal interconnect structures (612, 618, 622, 628, 632, 638, 642, 648) are herein referred to lower-level metal interconnect structures. A subset of the metal interconnect structures (612, 618, 622, 628, 632, 638, 642, 648) includes lower-level metal lines (such as the fourth metal line structures 648) that are embedded in the lower-level dielectric layers and having top surfaces within a horizontal plane including a topmost surface of the lower-level dielectric layers. Generally, the total number of metal line levels within the lower-level dielectric layers (601, 610, 620, 630, 640) may be in a range from 1 to 10.

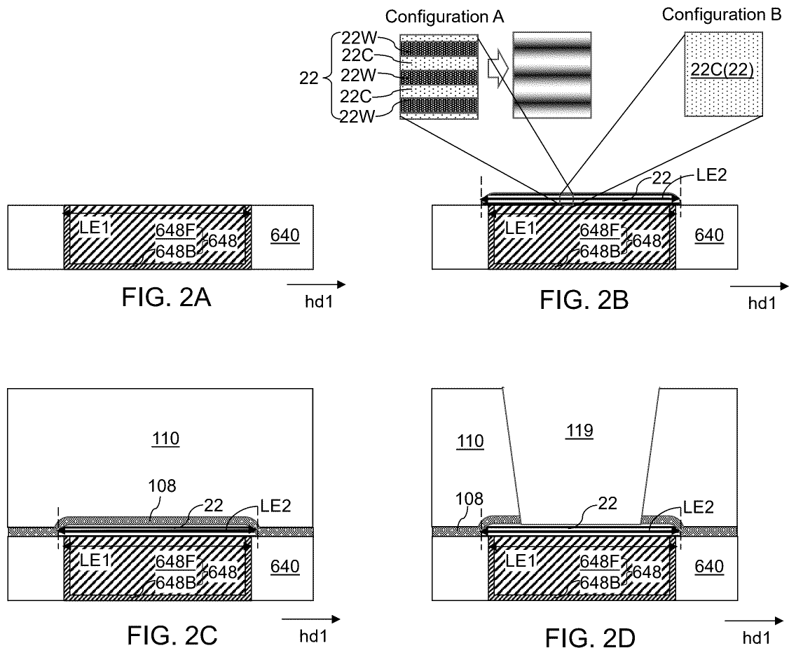

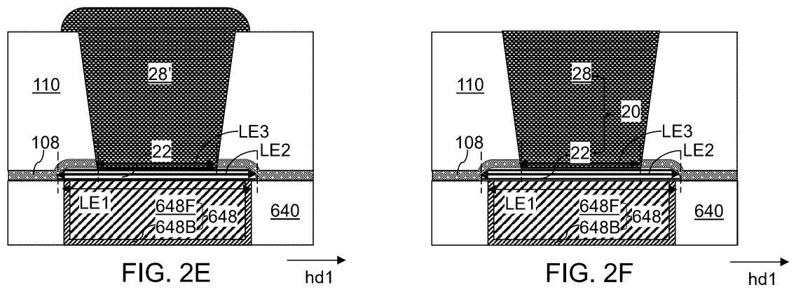

FIG. 2A-2F are sequential vertical cross-sectional views of a region of the exemplary structure during formation of a metallic via structure 20 comprising both a metal barrier liner 22 and a metal via fill structure 28, wherein the metallic via structure 20 may have a first configuration according to an embodiment of the present disclosure.

Referring to FIG. 2A, a region of the exemplary structure of FIG. 1 is illustrated, which includes a first metal interconnect structure (such as a fourth metal line structure 648) that is formed within a lower-level dielectric material layer (such as the fourth line-and-via-level dielectric material layer 640). The first metal interconnect structure may comprise a combination of a first metallic barrier liner 648B and a first metallic fill material portion 648F. The first metallic barrier liner 648B comprises a conductive metallic nitride material such as TiN, TaN, WN, MoN, or a combination thereof. The thickness of the first metallic barrier liner 648B may be in a range from 2 nm to 10 nm, although lesser or greater thicknesses may also be used. The first metallic fill material portion 648F comprises a metal having high electrical conductivity. In one embodiment, the first metallic fill material portion 648F comprises copper, tungsten, ruthenium, titanium, tantalum, molybdenum, or a combination thereof.

The top surface of the first metal interconnect structure (e.g., fourth metal line structure 648) may be formed entirely within a horizontal plane including the top surface of the lower-level dielectric material layer (such as the fourth line-and-via-level dielectric material layer 640). In one embodiment, the top surface of the first metal interconnect structure (such as a fourth metal line structure 648) has a first lateral extent LE1 along a first horizontal direction hd1. The first lateral extent LE1 may be in a range from 50 nm to 300 nm, although lesser or greater first lateral extents LE1 may also be used.

Referring to FIG. 2B, a cobalt-containing metal barrier liner 22 may be formed on the entirety of the physically exposed top surface of the first metal interconnect structure (such as a fourth metal line structure 648). The cobalt-containing metal barrier liner 22 comprises, and/or consists of, a cobalt-containing metallic material that is free of nitrogen. In one embodiment, the cobalt-containing metal barrier liner 22 comprises cobalt, and consists of at least one elemental metal including cobalt and optionally including tungsten.

In one embodiment, the cobalt-containing metal barrier liner 22 comprises, and/or consists essentially of, cobalt and tungsten. In one embodiment, the cobalt-containing metal barrier liner 22 may be formed by performing an alternating sequence of cobalt deposition steps and tungsten deposition steps. In this embodiment, the cobalt-containing metal barrier liner 22 comprises an alternating sequence of cobalt layers 22C and tungsten layers 22W that alternate along the growth direction as illustrated in the inset labeled “configuration A.” The total number of the cobalt layers 22C may be in a range from 2 to 6, and the total number of the tungsten layers 22W may be in a range from 2 to 6.

Optionally, an anneal process may be subsequently performed to induce interdiffusion of cobalt and tungsten. In this embodiment, the cobalt-containing metal barrier liner 22 may have a compositional modulation in the growth direction such that the atomic percentage of cobalt modulates along the growth direction, and the atomic percentage of tungsten modulates along the growth direction. The sum of the atomic percentage of cobalt and the atomic percentage of tungsten equals 100% at any point within the cobalt-containing metal barrier liner 22. The atomic percentage of cobalt may be within a range from 5% to 95%, and/or within a range from 10% to 90%, and/or within a range from 25% to 75%. The average atomic percentage of cobalt within the cobalt-containing metal barrier liner 22 may be in a range from 30% to 70%, such as from 40% to 60%, although lesser or greater average atomic percentages may also be used.

In an alternative embodiment, the cobalt-containing metal barrier liner 22 may be formed by deposition of tungsten. In this embodiment, the cobalt-containing metal barrier liner 22 consists of a single cobalt layer 22C as illustrated in the inset labeled “configuration B.”

In one embodiment, the cobalt-containing metal barrier liner 22 may be formed by performing a selective metal deposition process that grows at least one metal comprising cobalt and optionally comprising tungsten from a physically exposed top surface segment of the first metal interconnect structure (such as a fourth metal line structure 648) while suppressing growth of the at least one metal from dielectric surfaces (such as the top surface of the fourth line-and-via-level dielectric material layer 640).

In one embodiment, the at least one metal comprises a combination of cobalt and tungsten, and the cobalt-containing metal barrier liner 22 is formed by alternately performing selective cobalt deposition steps and tungsten deposition steps.

In one embodiment, each of the cobalt deposition steps may comprise a first atomic layer deposition (ALD) process that uses a cobalt-containing precursor gas to deposit a cobalt layer 22C while suppressing growth of cobalt on physically exposed dielectric surfaces, such as the top surface of the fourth line-and-via-level dielectric material layer 640. The cobalt-containing precursor gas may be selected from cobalt(II) acetylacetonate (Co(C₅H₇O₂)₂), dicobalt octacarbonyl (Co₂(CO)₈), or cyclopentadienylcobalt dicarbonyl (CoCp(CO)₂). Additionally, area-selective atomic layer deposition (AS-ALD) techniques may be utilized, such as using octadecyltrichlorosilane (ODTS) self-assembled monolayers (SAMs) to inhibit nucleation on dielectric surfaces. For example, the exemplary structure may be disposed within a process chamber, and the process chamber may be maintained under conditions suitable for ALD, such as a temperature range of 100 °C to 300 °C and a pressure range of 0.1 to 10 Torr. The cobalt deposition process may further involve hydrogen-assisted growth to enhance selectivity, suppressing unwanted nucleation on SiO₂ surfaces.

In one embodiment, each of the tungsten deposition steps may comprise a second atomic layer deposition process that uses a tungsten-containing precursor gas to deposit a tungsten layer 22W while suppressing growth of tungsten on physically exposed dielectric surfaces, such as the top surface of the fourth line-and-via-level dielectric material layer 640. The tungsten-containing precursor gas may be selected from tungsten hexafluoride (WF₆) or tungsten hexachloride (WCl₆). Adding H₂ during the WF₆ dose step has been shown to passivate SiO₂ against tungsten nucleation, thereby improving selectivity. For example, the exemplary structure may be disposed within a process chamber, and the process chamber may be maintained under conditions suitable for ALD, such as a temperature range of 200 °C to 400 °C and a pressure range of 0.1 to 10 Torr.

Optionally, following the alternating deposition of cobalt and tungsten layers, a thermal annealing process may be performed to induce interdiffusion, forming a mixed cobalt-tungsten (CoW) alloy barrier. This annealing step may be conducted at a temperature range of 300 °C to 500 °C under an inert atmosphere such as argon or forming gas (N₂/H₂ mixture). The cobalt-containing metal barrier liner 22 after the anneal step may exhibit compositional modulation along the growth direction, where the atomic percentage of cobalt varies from 5% to 95%, with an average composition of 30% to 70% cobalt.

In one embodiment, each of the selective cobalt deposition steps may comprise a respective first area-selective atomic layer deposition (AS-ALD) process that uses a cobalt-containing precursor gas, ensuring controlled deposition of cobalt on exposed metal surfaces while suppressing growth on dielectric surfaces such as silicon dioxide or low-k materials. Similarly, each of the selective tungsten deposition steps may comprise a respective second AS-ALD process that uses a tungsten-containing precursor gas, facilitating precise deposition of tungsten on targeted metal regions while minimizing unintended nucleation on surrounding dielectric materials. These AS-ALD processes leverage self-assembled monolayers (SAMs) or hydrogen passivation techniques to enhance selectivity and mitigate against non-uniform film growth.

In an alternative embodiment, the cobalt-containing metal barrier liner 22 may comprise, and consist essentially of, cobalt. In such an embodiment, the cobalt deposition process is designed to form a uniform cobalt layer 22C without tungsten interlayers, ensuring that the liner remains free from tungsten contamination. This may be achieved using a dedicated cobalt ALD process that uses cobalt precursors such as dicobalt octacarbonyl (Co₂(CO)₈) or cyclopentadienylcobalt dicarbonyl (CoCp(CO)₂) in combination with a suitable reducing agent, such as hydrogen gas (H₂) or plasma-enhanced ALD conditions. The resulting cobalt barrier liner exhibits enhanced diffusion barrier properties, effectively preventing copper ion migration while maintaining low electrical resistivity.

Generally, the cobalt-containing metal barrier liner 22 may be formed by selective deposition of cobalt and optionally tungsten while suppressing growth of these metals on dielectric surfaces, such as the top surface of the fourth line-and-via-level dielectric material layer 640. This selective deposition process ensures that the barrier liner is confined to the intended conductive regions, mitigating against unwanted nucleation that could impact device performance. In one embodiment, area-selective atomic layer deposition (AS-ALD) techniques may be used to achieve this selectivity. For example, octadecyltrichlorosilane (ODTS) self-assembled monolayers (SAMs) may be applied to dielectric surfaces, forming an inhibitory layer that mitigates cobalt nucleation while allowing deposition on exposed metal surfaces. The use of AS-ALD, particularly SAM-assisted inhibition techniques and hydrogen-based nucleation suppression, ensures that metal deposition occurs only on the desired conductive areas, reducing defects and improving device reliability.

In one embodiment, the cobalt-containing metal barrier liner 22 may be formed by performing a selective metal deposition process that grows at least one metal comprising cobalt from a physically exposed top surface segment of the first metal interconnect structure (such as a fourth metal line structure 648), while suppressing growth of the at least one metal from dielectric surfaces. The selectivity of this deposition process may be achieved through chemical inhibition mechanisms that involve hydrogen passivation of SiO₂ surfaces during tungsten deposition. Specifically, adding H₂ during the WF₆ dose step in atomic layer deposition (ALD) passivates SiO₂ against tungsten nucleation, thereby improving deposition selectivity.

The thickness of the cobalt-containing metal barrier liner 22 may be in a range from 1 nm to 20 nm, such as from 2 nm to 10 nm, although lesser or greater thicknesses may also be used depending on process conditions and performance requirements. The thickness of the cobalt-containing metal barrier liner 22 may be precisely controlled through ALD process parameters to balance diffusion barrier effectiveness with electrical conductivity.

In another embodiment, the deposition of the cobalt-containing metal barrier liner 22 is carried out directly on the first metal interconnect structure (such as a fourth metal line structure 648). This ensures a direct and conformal interface with the underlying metal interconnect, enhancing adhesion and providing a robust barrier against copper ion migration. The incorporation of SAM-based inhibition for cobalt deposition and hydrogen passivation for tungsten deposition further improves the reliability and selectivity of the barrier liner, minimizing defects that could arise from unwanted nucleation on dielectric surfaces.

The bottom surface of the cobalt-containing metal barrier liner 22 may have a second lateral extent LE2 that is greater than the first lateral extent LE1 along the first horizontal direction hd1. In one embodiment, the second lateral extent LE2 may be greater than the first lateral extent LE1 by twice the thickness of the cobalt-containing metal barrier liner 22.

Referring to FIG. 2C, a dielectric cap layer 108 and a via-level dielectric layer 110 may be sequentially formed over the cobalt-containing metal barrier liner 22 and the dielectric material layer. For example, the dielectric cap layer 108 may be formed on the top surfaces of the cobalt-containing metal barrier liner 22 and on the top surface of the fourth line-and-via-level dielectric material layer 640. The dielectric cap layer 108 includes a dielectric capping material that protects underlying metal interconnect structures such as the cobalt-containing metal barrier liner 22. In one embodiment, the dielectric cap layer 108 may include a material that may provide high etch resistance, i.e., a dielectric material and also may function as an etch stop material during a subsequent anisotropic etch process that etches the via-level dielectric layer 110. For example, the dielectric cap layer 108 may include silicon carbide or silicon nitride, and may have a thickness in a range from 5 nm to 30 nm, although lesser and greater thicknesses may also be used.

The via-level dielectric layer 110 may include any material that may be used for the dielectric material layers (601, 610, 620, 630, 640). Other suitable dielectric materials are within the contemplated scope of disclosure. For example, the via-level dielectric layer 110 may include undoped silicate glass or a doped silicate glass deposited by decomposition of tetraethylorthosilicate (TEOS). The thickness of the via-level dielectric layer 110 may be in a range from 50 nm to 200 nm, although lesser and greater thicknesses may also be used. The dielectric cap layer 108 and the via-level dielectric layer 110 may be formed as planar blanket (unpatterned) layers having a respective planar top surface and a respective planar bottom surface that extends throughout the memory array region 100 and the peripheral region 200.

Referring to FIG. 2D, an anisotropic etch process is performed to form via cavities 119 such that a top surface segment of the cobalt-containing metal barrier liner 22 is exposed underneath each via cavity 119. For example, a photoresist layer (not shown) may be applied over the via-level dielectric layer 110, and may be lithographically patterned to form an array of openings over the areas of the cobalt-containing metal barrier liners 22 in the memory array region 100. The area of each opening in the photoresist layer may be located entirely within the periphery of a respective underlying cobalt-containing metal barrier liner 22. An anisotropic etch process may be performed to etch portions of the via-level dielectric layer 110 and the dielectric cap layer 108 that are not masked by the photoresist layer. In one embodiment, the anisotropic etch process may comprise a first anisotropic etch step that etches unmasked portions of the via-level dielectric layer 110 selectively to the material of the dielectric cap layer 108, and a second anisotropic etch step that etches unmasked portions of the dielectric cap layer 108 selectively to the material of the cobalt-containing metal barrier liners 22.

A via cavity 119 may be formed in each volume from which material portions of the via-level dielectric layer 110 and the dielectric cap layer 108 are removed. A top surface segment of a cobalt-containing metal barrier liner 22 may be physically exposed underneath each via cavity 119. Thus, each via cavity 119 may be formed through the via-level dielectric layer 110 and the dielectric cap layer 108. The photoresist layer may be subsequently removed, for example, by ashing or by dissolution in a solvent. Generally, a via-level dielectric layer 110 containing a via cavity 119 therethrough may be formed over the first metal interconnect structures (such as a fourth metal line structure 648).

Referring to FIG. 2E, a metal may be deposited in the volumes of the via cavities 119 to form in-process metal via fill structures 28′. As used herein, an “in-process” element refers to an element that is subsequently modified in material composition and/or shape. In one embodiment, the metal may be deposited in the via cavities 119 by a selective deposition process that grows only from metallic surfaces and does not grow from dielectric surfaces, i.e., without growing the metal from the physically exposed surfaces of the via-level dielectric layer 110. The selective deposition process may grow an in-process metal via fill structure 28 within each via cavity 119 from bottom to top such that the via cavity 119 is filled with the in-process metal via fill structure 28 without a void.

In one embodiment, the metal may be tungsten, which is deposited using a tungsten-containing precursor gas that nucleates only on metallic surfaces. The tungsten-containing precursor gas may comprise tungsten hexafluoride (WF₆), tungsten hexachloride (WCl₆), or tungsten carbonyl (W(CO)₆). The deposition process may be carried out using chemical vapor deposition (CVD) or atomic layer deposition (ALD), with hydrogen (H₂) or silane (SiH₄) as a reducing agent to promote selective growth on exposed cobalt-containing metal barrier liners while mitigating against the deposition on dielectric surfaces. Additionally, hydrogen passivation may be applied during the WF₆ dose step to suppress unwanted nucleation on silicon dioxide (SiO₂), thereby enhancing the selectivity of the deposition process. Each deposited metal portion constitutes an in-process metal via fill structure 28′ that fills a respective via cavity 119. Each in-process metal via fill structure 28′ may have a bottom surface having a respective third lateral extent LE3 along the first horizontal direction hd1. In one embodiment, the third lateral extent LE3 of each in-process metal via fill structure 28′ may be less than the first lateral extent LE1 of a respective underlying first metal interconnect structure.

Referring to FIG. 2F, excess metal overburdens of the in-process metal via fill structures 28′ may be removed from above the horizontal plane including the top surface of the via-level dielectric layer 110, for example, by performing a planarization process such as chemical mechanical planarization (CMP). Each remaining portion of the in-process metal via fill structures 28′ constitutes a metal via fill structure 28. Generally, a metal via fill structure 28 may be formed over a cobalt-containing metal barrier liner 22 within the via cavity 119. In one embodiment, the metal via fill structures 28 comprise, and/or consist essentially of, tungsten. Each metal via fill structure 28 has a third lateral extent LE3 along the first horizontal direction hd1 that is less than the first lateral extent LE1 of a respective underlying first metal interconnect structure. Each contiguous combination of a cobalt-containing metal barrier liner 22 and a metal via fill structure 28 constitutes a metallic via structure 20.

According to an embodiment of the present disclosure, a device structure may include a first metal interconnect structure such as fourth metal line structure 648, which is embedded within lower-level dielectric material layer 640 over substrate 9. A metal via fill structure 28 is located above the first metal interconnect structure and is enclosed within via-level dielectric layer 110. A cobalt-containing metal barrier liner 22 is formed directly on the top surface of the first metal interconnect structure, providing a diffusion barrier and maintaining electrical connectivity between the interconnect and the metallic via fill structure 28.

In one embodiment, the cobalt-containing metal barrier liner 22 consists of an alternating stack of cobalt layers 22C and tungsten layers 22W, which enhances its diffusion barrier properties and electrical performance. In another embodiment, the cobalt-containing metal barrier liner 22 consists entirely of cobalt, ensuring strong adhesion to the first metal interconnect structure and compatibility with surrounding metal layers.

The cobalt-containing metal barrier liner 22 extends beyond the periphery of first metal interconnect structure 648. The top surface of the first metal interconnect structure has a first lateral extent LE1 along first horizontal direction hd1, while the bottom surface of the cobalt-containing metal barrier liner 22 has a second lateral extent LE2 that is greater than the first lateral extent LE1 along first horizontal direction hd1. The increased lateral extent of the cobalt-containing metal barrier liner 22 improves electrical contact, enhances adhesion, and strengthens the overall structural integrity of the device.

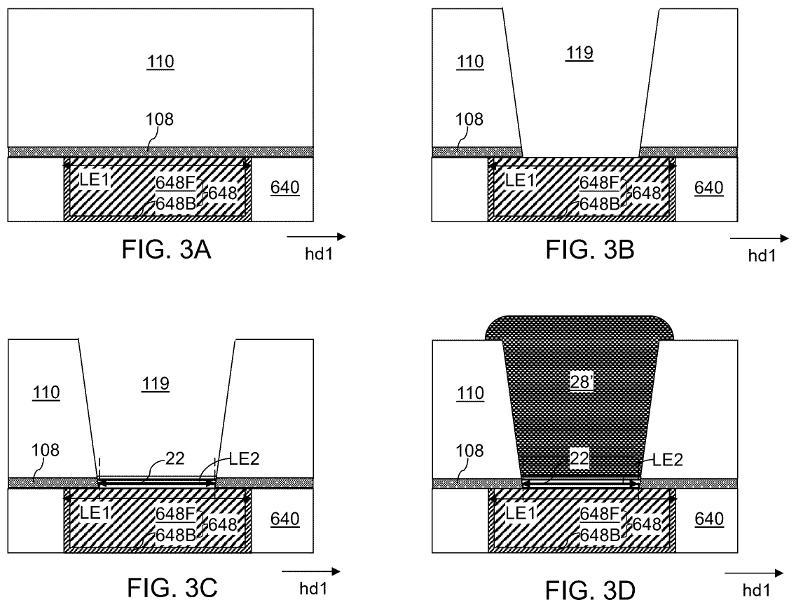

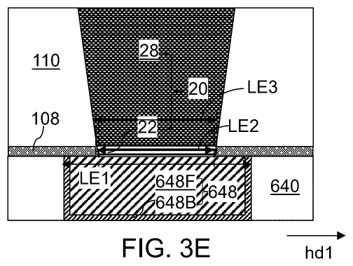

FIG. 3A-3E are sequential vertical cross-sectional views of a region of the exemplary structure during formation of a metallic via structure 20 having a second configuration according to an embodiment of the present disclosure.

Referring to FIG. 3A, a region of the exemplary structure is illustrated, which may be derived from the exemplary structure illustrated in FIG. 2A by depositing a dielectric cap layer 108 and a via-level dielectric layer 110. The dielectric cap layer 108 may be formed directly on the entirety of the top surface of each first metal interconnect structure (such as the fourth metal line structures 648) and on the entirety of the top surface of the dielectric material layer (such as the fourth line-and-via-level dielectric material layer 640) having formed therein the first metal interconnect structures. The dielectric cap layer 108 and the via-level dielectric layer 110 may be the same as described above.

Referring to FIG. 3B, an anisotropic etch process is performed to form via cavities 119 such that a top surface segment of a respective first metal interconnect structure (such as a respective fourth metal line structure 648) is exposed underneath each via cavity 119. For example, a photoresist layer (not shown) may be applied over the via-level dielectric layer 110, and may be lithographically patterned to form an array of openings over the areas of the first metal interconnect structures in the memory array region 100. The area of each opening in the photoresist layer may be located entirely within the periphery of a respective underlying first metal interconnect structure. An anisotropic etch process may be performed to etch portions of the via-level dielectric layer 110 and the dielectric cap layer 108 that are not masked by the photoresist layer. In one embodiment, the anisotropic etch process may comprise a first anisotropic etch step that etches unmasked portions of the via-level dielectric layer 110 selectively to the material of the dielectric cap layer 108, and a second anisotropic etch step that etches unmasked portions of the dielectric cap layer 108 selectively to the material of the first metal interconnect structures.

A via cavity 119 may be formed in each volume from which material portions of the via-level dielectric layer 110 and the dielectric cap layer 108 are removed. A top surface segment of a first metal interconnect structure may be physically exposed underneath each via cavity 119. Thus, each via cavity 119 may be formed through the via-level dielectric layer 110 and the dielectric cap layer 108. The photoresist layer may be subsequently removed, for example, by ashing or by dissolution in a solvent. Generally, a via-level dielectric layer 110 containing a via cavity 119 therethrough may be formed over the first metal interconnect structures (such as a fourth metal line structure 648).

Referring to FIG. 3C, a cobalt-containing metal barrier liner 22 may be formed on the physically exposed top surface of the first metal interconnect structure (such as a fourth metal line structure 648) underneath each via cavity 119. The cobalt-containing metal barrier liner 22 comprises, and/or consists of, a cobalt-containing metallic material that is free of nitrogen. In one embodiment, the cobalt-containing metal barrier liner 22 comprises cobalt, and consists of at least one elemental metal including cobalt and optionally including tungsten.

In one embodiment, the cobalt-containing metal barrier liner 22 comprises, and/or consists essentially of, cobalt and tungsten. In one embodiment, the cobalt-containing metal barrier liner 22 is formed by performing an alternating sequence of cobalt deposition steps and tungsten deposition steps. In this embodiment, the cobalt-containing metal barrier liner 22 comprises an alternating sequence of cobalt layers and tungsten layers that alternate along the growth direction as described with reference to FIG. 2B. The total number of the cobalt layers may be in a range from 2 to 6, and the total number of the tungsten layers may be in a range from 2 to 6.

Optionally, an anneal process may be subsequently performed to induce interdiffusion of cobalt and tungsten. In this embodiment, the cobalt-containing metal barrier liner 22 may have a compositional modulation in the growth direction such that the atomic percentage of cobalt modulates along the growth direction, and the atomic percentage of tungsten modulates along the growth direction. The sum of the atomic percentage of cobalt and the atomic percentage of tungsten equals 100% at any point within the cobalt-containing metal barrier liner 22. The atomic percentage of cobalt may be within a range from 5% to 95%, and/or within a range from 10% to 90%, and/or within a range from 25% to 75%. The average atomic percentage of cobalt within the cobalt-containing metal barrier liner 22 may be in a range from 30% to 70%, such as from 40% to 60%, although lesser or greater average atomic percentages may also be used.

In an alternative embodiment, the cobalt-containing metal barrier liner 22 may be formed by deposition of tungsten. In this embodiment, the cobalt-containing metal barrier liner 22 consists of a single cobalt layer as described with reference to FIG. 2B.

In one embodiment, the cobalt-containing metal barrier liner 22 is formed by performing a selective metal deposition process that grows at least one metal comprising cobalt and optionally comprising tungsten from a physically exposed top surface segment of the first metal interconnect structure (such as a fourth metal line structure 648) while suppressing growth of the at least one metal from dielectric surfaces (such as the top surface of the fourth line-and-via-level dielectric material layer 640).

In one embodiment, the at least one metal comprises a combination of cobalt and tungsten, and the cobalt-containing metal barrier liner 22 is formed by alternately performing selective cobalt deposition steps and tungsten deposition steps as described with reference to FIG. 2B. In an alternative embodiment, the cobalt-containing metal barrier liner 22 may comprise, and consist essentially of, cobalt as described with reference to FIG. 2B. Generally, any selective deposition process for forming a cobalt-containing metal barrier liner 22 as described with reference to FIG. 2B may be used to form the cobalt-containing metal barrier liner 22 in FIG. 3C.

Generally, the cobalt-containing metal barrier liner 22 of FIG. 3C may be formed by selective deposition of cobalt and tungsten while suppressing growth of these metals on dielectric surfaces, such as the top surface of the fourth line-and-via-level dielectric material layer 640. This selective deposition process ensures that the barrier liner is confined to the intended conductive regions, mitigating against unwanted nucleation that could impact device performance. In one embodiment, area-selective atomic layer deposition (AS-ALD) techniques may be used to achieve this selectivity. For example, octadecyltrichlorosilane (ODTS) self-assembled monolayers (SAMs) may be applied to dielectric surfaces, forming an inhibitory layer that mitigates against cobalt nucleation while allowing deposition on exposed metal surfaces. The use of AS-ALD, particularly SAM-assisted inhibition techniques and hydrogen-based nucleation suppression, ensures that metal deposition occurs only on the desired conductive areas, reducing defects and improving device reliability.

In one embodiment, the cobalt-containing metal barrier liner 22 is formed by performing a selective metal deposition process that grows at least one metal comprising cobalt from a physically exposed top surface segment of the first metal interconnect structure (such as a fourth metal line structure 648), while suppressing growth of the at least one metal from dielectric surfaces. The selectivity of this deposition process may be achieved through chemical inhibition mechanisms that involve hydrogen passivation of SiO₂ surfaces during tungsten deposition. Specifically, adding H₂ during the WF₆ dose step in atomic layer deposition (ALD) passivates SiO₂ against tungsten nucleation, thereby improving deposition selectivity.

The thickness of the cobalt-containing metal barrier liner 22 may be in a range from 1 nm to 20 nm, such as from 2 nm to 10 nm, although lesser or greater thicknesses may also be used depending on process conditions and performance requirements. The thickness of the cobalt-containing metal barrier liner 22 may be precisely controlled through ALD process parameters to balance diffusion barrier effectiveness with electrical conductivity.

The cobalt-containing metal barrier liner 22 of FIG. 3C may be formed only at the bottom of each via cavity 119, and does not nucleate from the dielectric surfaces of the via-level dielectric layer 110. Thus, each cobalt-containing metal barrier liner 22 of FIG. 3C has a respective second lateral extent LE2 that is less than the first lateral extent LE1 of a respective underlying first metal interconnect structure (such as a fourth metal line structure 648). The entirety of each cobalt-containing metal barrier liner 22 may be located between a first horizontal plane including the top surfaces of the first metal interconnect structures (such as the fourth metal line structure 648) and another second horizontal plane that is vertically offset from the first horizontal plane by the thickness of the cobalt-containing metal barrier liner 22.

Referring to FIG. 3D, a metal may be deposited in the volumes of the via cavities 119 to form in-process metal via fill structures 28′. The processing steps described with reference to FIG. 2E may be performed to form the in-process metal via fill structures 28′. Each in-process metal via fill structure 28′ may have a bottom surface having a respective third lateral extent LE3 along the first horizontal direction hd1. In one embodiment, the third lateral extent LE3 of each in-process metal via fill structure 28′ may be less than the first lateral extent LE1 of a respective underlying first metal interconnect structure.

Referring to FIG. 3E, excess metal overburdens of the in-process metal via fill structures 28′ may be removed from above the horizontal plane including the top surface of the via-level dielectric layer 110, for example, by performing a planarization process such as chemical mechanical planarization (CMP). Each remaining portion of the in-process metal via fill structures 28′ constitutes a metal via fill structure 28. Generally, a metal via fill structure 28 is formed over a cobalt-containing metal barrier liner 22 within the via cavity 119. In one embodiment, the metal via fill structures 28 comprise, and/or consist essentially of, tungsten. Each metal via fill structure 28 may have a third lateral extent LE3 along the first horizontal direction hd1 that is less than the first lateral extent LE1 of a respective underlying first metal interconnect structure. Each contiguous combination of a cobalt-containing metal barrier liner 22 and a metal via fill structure 28 constitutes a metallic via structure 20.

According to an embodiment of the present disclosure, a device structure includes a first metal interconnect structure such as fourth metal line structure 648, which is formed within lower-level dielectric material layer 640 over substrate 9. A metal via fill structure 28 is located above the first metal interconnect structure and is enclosed within via-level dielectric layer 110. A cobalt-containing metal barrier liner 22 is formed directly on the top surface of the first metal interconnect structure, providing a diffusion barrier and maintaining electrical connectivity between the interconnect and the metallic via fill structure 28.

In one embodiment, the cobalt-containing metal barrier liner 22 consists of an alternating stack of cobalt layers and tungsten layers, which enhances its diffusion barrier properties and electrical performance. In another embodiment, the cobalt-containing metal barrier liner 22 consists entirely of cobalt, ensuring strong adhesion to the first metal interconnect structure and compatibility with surrounding metal layers.

The cobalt-containing metal barrier liner 22 may be located entirely within the area of a respective underlying first metal interconnect structure 648. The top surface of the first metal interconnect structure has a first lateral extent LE1 along first horizontal direction hd1, while the bottom surface of the cobalt-containing metal barrier liner 22 has a second lateral extent LE2 that is less than the first lateral extent LE1 along first horizontal direction hd1.

In all configurations of the present disclosure described above and to be subsequently described, a cobalt-containing metal barrier liner 22 on a physically exposed top surface segment of the first metal interconnect structure (such as a fourth metal line structure 648) prior to, or after, formation of the via-level dielectric layer 110 and the via cavity 119. In embodiments in which the via cavity 119 is formed after formation of the cobalt-containing metal barrier liner 22, a surface of the cobalt-containing metal barrier liner 22 is exposed at least at a bottom of the via cavity 119. If the via cavity 119 is formed prior to formation of the cobalt-containing metal barrier liner 22, a surface of a first metal interconnect structure (such as a fourth metal line structure 648) is exposed at least at a bottom of the via cavity 119.

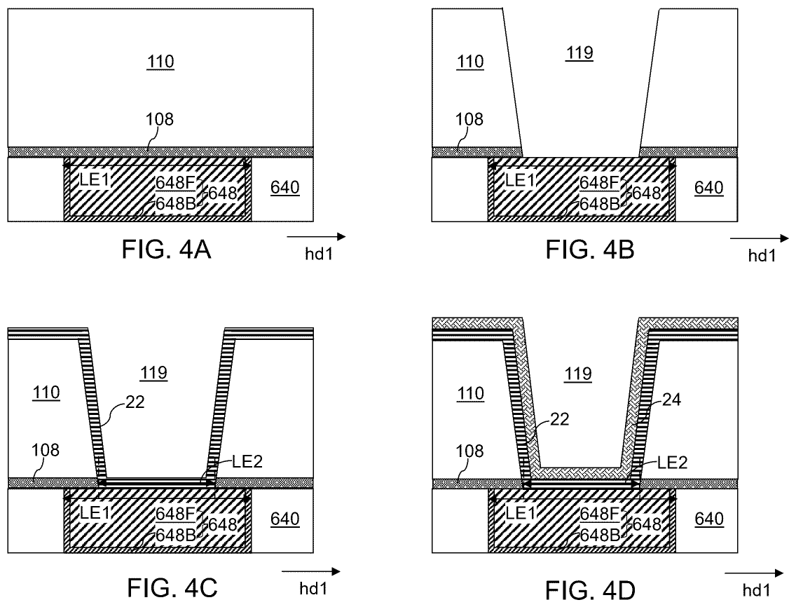

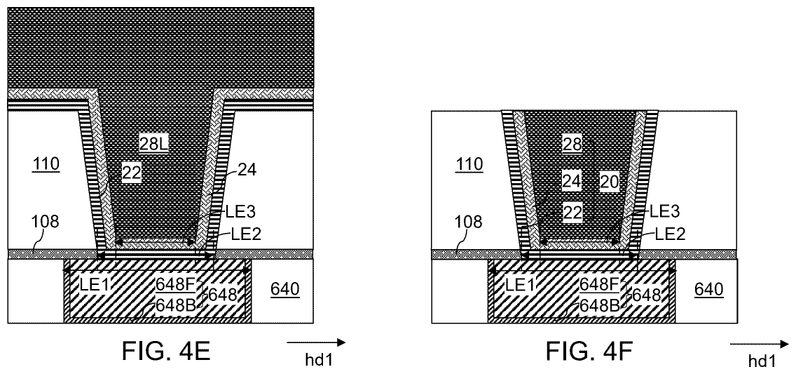

FIG. 4A-4F are sequential vertical cross-sectional views of a region of the exemplary structure during formation of a metallic via structure 20 having a third configuration according to an embodiment of the present disclosure.

Referring to FIG. 4A, a region of the exemplary structure is illustrated, which may be the same as the exemplary structure illustrated in FIG. 3A.

Referring to FIG. 4B, the processing steps described with reference to FIG. 3B may be performed to form via cavities 119 through the via-level dielectric layer 110 and the dielectric cap layer 108. A top surface segment of a respective first metal interconnect structure (such as a respective fourth metal line structure 648) is exposed underneath each via cavity 119.

Referring to FIG. 4C, a cobalt-containing metal barrier liner 22 may be formed on the physically exposed top surface of the first metal interconnect structure (such as a fourth metal line structure 648) underneath each via cavity 119 and on the physically exposed surfaces of the via-level dielectric layer 110. The cobalt-containing metal barrier liner 22 may have any material composition discussed with reference to FIGS. 2B and 3C. However, the deposition process that forms the cobalt-containing metal barrier liner 22 may be modified such that the cobalt-containing metal barrier liner 22 is formed non-selectively on all physically exposed surfaces of the first metal interconnect structures and the via-level dielectric layer 110.

The non-selective deposition of the cobalt-containing metal barrier liner 22 may form a conformal cobalt-containing metal barrier liner 22 over all physically exposed surfaces, including the top surfaces of the first metal interconnect structure (such as a fourth metal line structure 648) and the physically exposed surfaces of the via-level dielectric layer 110. In one embodiment, the non-selective deposition process may comprise a chemical vapor deposition (CVD) process. In this embodiment, the exemplary structure is exposed to a cobalt-containing precursor gas, such as dicobalt hexacarbonyl butylacetylene (CCTBA), in the presence of a reducing agent, such as hydrogen (H₂). The process conditions, including substrate temperature and gas flow rates, may be controlled to achieve a uniform cobalt-containing metal barrier liner 22 of a target thickness, which may be in a range from 1 nm to 20 nm.

In another embodiment, the non-selective deposition process may comprise an atomic layer deposition (ALD) process, which provides precise thickness control and conformal coverage over high-aspect-ratio structures. The ALD process may use alternating pulses of a cobalt-containing precursor gas and a reducing agent, wherein the precursor gas may include cobalt(II) acetylacetonate (Co(C₅H₇O₂)₂) or cyclopentadienylcobalt dicarbonyl (CoCp(CO)₂), and the reducing agent may include hydrogen (H₂) or plasma-enhanced reducing species.

In an alternative embodiment, the cobalt-containing metal barrier liner 22 may be formed by electroless deposition, wherein a catalytic surface initiates the chemical reduction of cobalt ions from a deposition solution, leading to metal deposition without the need for an external electrical current. The electroless deposition process may be used to ensure uniform coverage of the cobalt-containing metal barrier liner 22 across both metallic and dielectric surfaces.

Referring to FIG. 4D, a conductive metallic nitride liner 24 may be deposited over the cobalt-containing metal barrier liner 22. The conductive metallic nitride liner 24 comprises, and/or consists essentially of, at least one conductive metallic nitride material such as TiN, TaN, WN, and/or MoN. In one embodiment, the conductive metallic nitride liner 24 may be a TiN layer. The conductive metallic nitride liner 24 may be formed by chemical vapor deposition, atomic layer deposition, and/or physical vapor deposition. The thickness of the conductive metallic nitride liner 24 may be in a range from 1 nm to 20 nm, such as from 2 nm to 10 nm, although lesser or greater thicknesses may also be used.

Referring to FIG. 4E, a metal may be deposited in the remaining volumes of the via cavities 119 to form in-process metal via fill structures 28′. The processing steps described with reference to FIG. 2E may be performed to form the in-process metal via fill structures 28′. Each in-process metal via fill structure 28′ may have a bottom surface having a respective third lateral extent LE3 along the first horizontal direction hd1. In one embodiment, the third lateral extent LE3 of each in-process metal via fill structure 28′ may be less than the first lateral extent LE1 of a respective underlying first metal interconnect structure.

Referring to FIG. 4F, excess metal overburdens of the in-process metal via fill structures 28', the conductive metallic nitride liner 24, and the cobalt-containing metal barrier liner 22 may be removed from above the horizontal plane including the top surface of the via-level dielectric layer 110, for example, by performing a planarization process such as chemical mechanical planarization (CMP). Each remaining portion of the in-process metal via fill structures 28′ constitutes a metal via fill structure 28. The conductive metallic nitride liner 24 may be divided into a plurality of conductive metallic nitride liners 24 located within a respective one of the via cavities 119. The cobalt-containing metal barrier liner 22 may be divided into a plurality of cobalt-containing metal barrier liners 22 located within a respective one of the via cavities 119.

In the third configuration illustrated in FIG. 4F, each metal via fill structure 28 is formed over a conductive metallic nitride liner 24 and a cobalt-containing metal barrier liner 22 within the via cavity 119. In one embodiment, the metal via fill structures 28 comprise, and/or consist essentially of, tungsten. Each metal via fill structure 28 has a third lateral extent LE3 along the first horizontal direction hd1 that is less than the first lateral extent LE1 of a respective underlying first metal interconnect structure. Each contiguous combination of a cobalt-containing metal barrier liner 22, a conductive metallic nitride liner 24, and a metal via fill structure 28 constitutes a metallic via structure 20.

According to an embodiment of the present disclosure, a device structure includes a first metal interconnect structure such as fourth metal line structure 648, which is embedded within lower-level dielectric material layer 640 over substrate 9. A metal via fill structure 28 is located above the first metal interconnect structure and is enclosed within via-level dielectric layer 110. A cobalt-containing metal barrier liner 22 is formed directly on the top surface of the first metal interconnect structure, providing a diffusion barrier and maintaining electrical connectivity between the interconnect and the metallic via fill structure 28.

In one embodiment, the cobalt-containing metal barrier liner 22 consists of an alternating stack of cobalt layers and tungsten layers, which enhances its diffusion barrier properties and electrical performance. In another embodiment, the cobalt-containing metal barrier liner 22 consists entirely of cobalt, ensuring strong adhesion to the first metal interconnect structure and compatibility with surrounding metal layers.

The cobalt-containing metal barrier liner 22 is located entirely within the area of a respective underlying first metal interconnect structure 648. The top surface of the first metal interconnect structure has a first lateral extent LE1 along first horizontal direction hd1, while the bottom surface of the cobalt-containing metal barrier liner 22 has a second lateral extent LE2 that is less than the first lateral extent LE1 along first horizontal direction hd1.

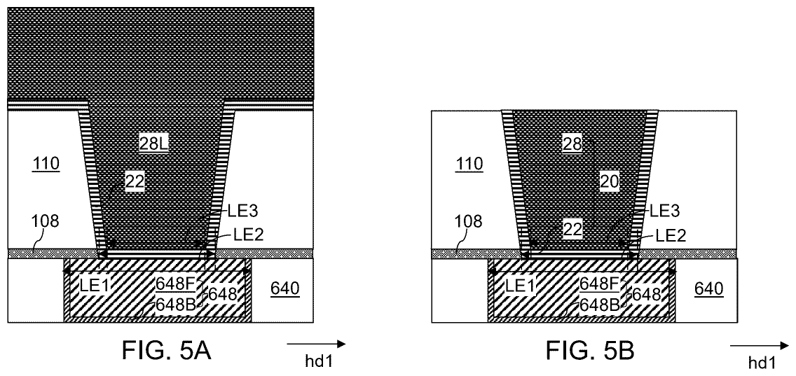

FIGS. 5A and 5B are sequential vertical cross-sectional views of a region of the exemplary structure during formation of a metallic via structure 20 having a fourth configuration according to an embodiment of the present disclosure.

Referring to FIG. 5A, a region of the exemplary structure is illustrated, which may be derived from the exemplary structure illustrated in FIG. 4C by depositing a metal in the remaining volumes of the via cavities 119 to form in-process metal via fill structures 28′. Thus, the processing steps described with reference to FIG. 4D may be omitted. The processing steps described with reference to FIG. 2E may be performed to form the in-process metal via fill structures 28′. Each in-process metal via fill structure 28′ may have a bottom surface having a respective third lateral extent LE3 along the first horizontal direction hd1. In one embodiment, the third lateral extent LE3 of each in-process metal via fill structure 28′ may be less than the first lateral extent LE1 of a respective underlying first metal interconnect structure.

Referring to FIG. 5B, excess metal overburdens of the in-process metal via fill structures 28′ and the cobalt-containing metal barrier liner 22 may be removed from above the horizontal plane including the top surface of the via-level dielectric layer 110, for example, by performing a planarization process such as chemical mechanical planarization (CMP). Each remaining portion of the in-process metal via fill structures 28′ constitutes a metal via fill structure 28. The cobalt-containing metal barrier liner 22 is divided into a plurality of cobalt-containing metal barrier liners 22 located within a respective one of the via cavities 119.

In the fourth configuration illustrated in FIG. 5B, each metal via fill structure 28 is formed over a cobalt-containing metal barrier liner 22 within the via cavity 119. In one embodiment, the metal via fill structures 28 comprise, and/or consist essentially of, tungsten. Each metal via fill structure 28 may have a third lateral extent LE3 along the first horizontal direction hd1 that is less than the first lateral extent LE1 of a respective underlying first metal interconnect structure. Each contiguous combination of a cobalt-containing metal barrier liner 22 and a metal via fill structure 28 constitutes a metallic via structure 20.

According to an embodiment of the present disclosure, a device structure includes a first metal interconnect structure such as fourth metal line structure 648, which is embedded within lower-level dielectric material layer 640 over substrate 9. A metal via fill structure 28 is located above the first metal interconnect structure and is enclosed within via-level dielectric layer 110. A cobalt-containing metal barrier liner 22 is formed directly on the top surface of the first metal interconnect structure, providing a diffusion barrier and maintaining electrical connectivity between the interconnect and the metallic via fill structure 28.

In one embodiment, the cobalt-containing metal barrier liner 22 consists of an alternating stack of cobalt layers and tungsten layers, which enhances its diffusion barrier properties and electrical performance. In another embodiment, the cobalt-containing metal barrier liner 22 consists entirely of cobalt, ensuring strong adhesion to the first metal interconnect structure and compatibility with surrounding metal layers.

The cobalt-containing metal barrier liner 22 may be located entirely within the area of a respective underlying first metal interconnect structure 648. The top surface of the first metal interconnect structure has a first lateral extent LE1 along first horizontal direction hd1, while the bottom surface of the cobalt-containing metal barrier liner 22 has a second lateral extent LE2 that is less than the first lateral extent LE1 along first horizontal direction hd1.

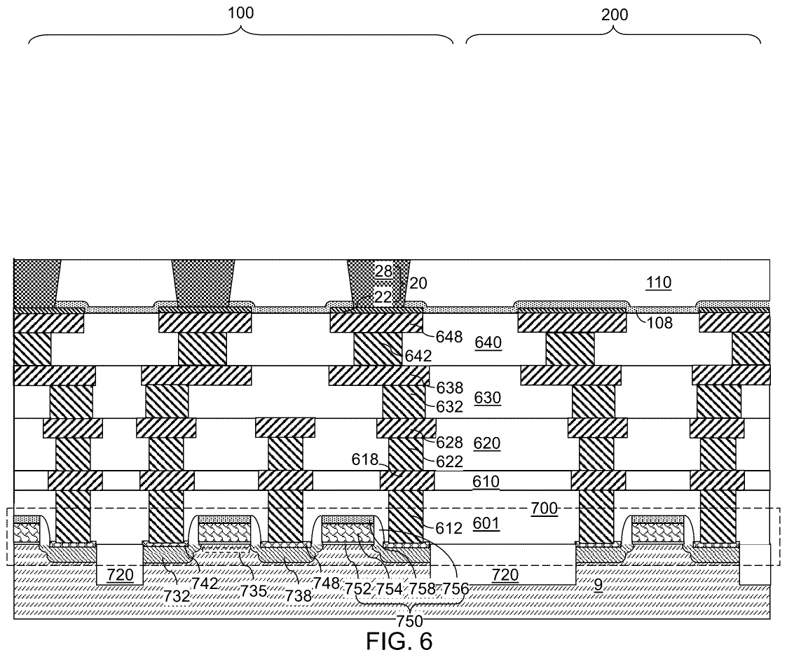

Referring to FIG. 6, the exemplary structure is illustrated after formation of an array of metallic via structures 20 according to an embodiment of the present disclosure. The array of metallic via structures 20 may contact top surfaces of a subset of the fourth metal line structures 648. Generally, the array of metallic via structures 20 contacts top surfaces of a subset of lower-level metal lines located at the topmost level of the lower-level dielectric layers (601, 610, 620, 630, 640).

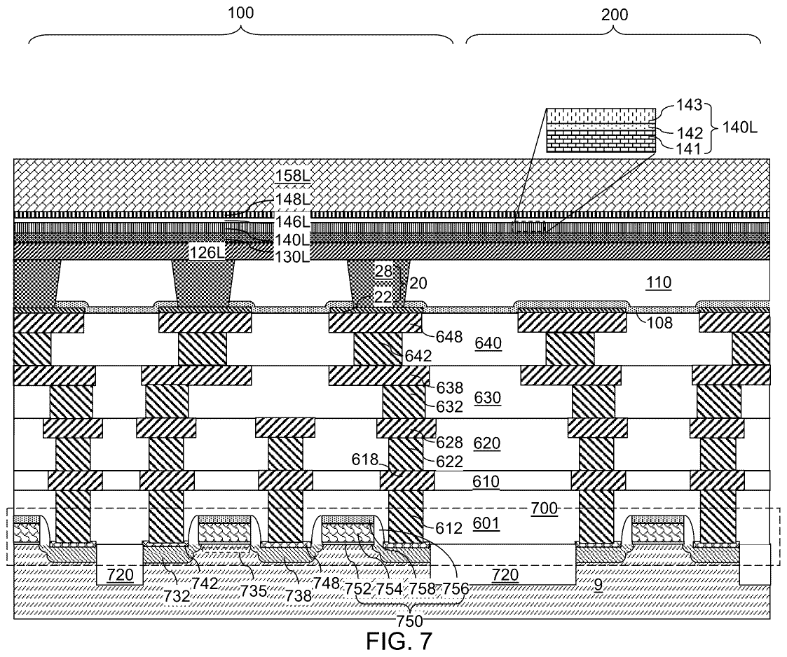

Referring to FIG. 7, a bottom electrode material layer 126L, a memory material layer stack (130L, 140L, 146L, 148L), and a top electrode material layer 158L may be formed over the via-level dielectric layer 110 and the array of metallic via structures 20 (22, 28).

The bottom electrode material layer 126L includes at least one nonmagnetic metallic material such as TiN, TaN, WN, W, Cu, Al, Ti, Ta, Ru, Mo, Pt, an alloy thereof, and/or a combination thereof. Other suitable materials within the contemplated scope of disclosure may also be used. For example, the bottom electrode material layer 126L may include, and/or may consist essentially of, an elemental metal such as W, Cu, Ti, Ta, Ru, Mo, or Pt. The thickness of the bottom electrode material layer 126L may be in a range from 10 nm to 100 nm, although lesser and greater thicknesses may also be used.

In one embodiment, the memory material layer stack (130L, 140L, 146L, 148L) may include, from bottom to top, an optional nonmagnetic metallic buffer material layer 130L, a synthetic antiferromagnet layer 140L, a nonmagnetic tunnel barrier material layer 146L, and a free magnetization material layer 148L. The layers within the memory material layer stack (130L, 140L, 146L, 148L) may be deposited by a respective chemical vapor deposition process or a respective physical vapor deposition process. Each layer within the memory material layer stack (130L, 140L, 146L, 148L) may be deposited as planar blanket material layers having a respective uniform thickness throughout. Generally, the memory material layer stack (130L, 140L, 146L, 148L) is formed between the bottom electrode material layer 126L and the top electrode material layer 158L.

The nonmagnetic metallic buffer material layer 130L includes a nonmagnetic material that may function as a seed layer. Specifically, the nonmagnetic metallic buffer material layer 130L may provide a template crystalline structure that aligns polycrystalline grains of the materials of the synthetic antiferromagnet layer 140L along a direction that maximizes the magnetization of a reference magnetization layer within the synthetic antiferromagnet layer 140L. The nonmagnetic metallic buffer material layer 130L may include Ti, a CoFeB alloy, a NiFe alloy, ruthenium, or a combination thereof. Other suitable materials are within the contemplated scope of disclosure. The thickness of the nonmagnetic metallic buffer material layer 130L may be in a range from 3 nm to 30 nm, although lesser and greater thicknesses may also be used.

The synthetic antiferromagnet (SAF) layer 140L may include a layer stack of a ferromagnetic hard layer 141, an antiferromagnetic coupling layer 142, and a reference magnetization layer 143. Each of the ferromagnetic hard layer 141 and the reference magnetization layer 143 may have a respective fixed magnetization direction. The antiferromagnetic coupling layer 142 provides antiferromagnetic coupling between the magnetization of the ferromagnetic hard layer 141 and the magnetization of the reference magnetization layer 143 so that the magnetization direction of the ferromagnetic hard layer 141 and the magnetization direction of the reference magnetization layer 143 remain fixed during operation of the memory cells to be subsequently formed. The ferromagnetic hard layer 141 may include a hard ferromagnetic material such as PtMn, IrMn, RhMn, FeMn, OsMn, etc. The reference magnetization layer 143 may include a hard ferromagnetic material such as Co, CoFe, CoFeB, CoFeTa, NiFe, CoPt, CoFeNi, etc. Other suitable materials within the contemplated scope of disclosure may also be used. The antiferromagnetic coupling layer 142 may include ruthenium or iridium. The thickness of the antiferromagnetic coupling layer 142 may be selected such that the exchange interaction induced by the antiferromagnetic coupling layer 142 stabilizes the relative magnetization directions of the ferromagnetic hard layer 141 and the reference magnetization layer 143 at opposite directions, i.e., in an antiparallel alignment. In one embodiment, the net magnetization of the SAF layer 140L may be determined by matching the magnitude of the magnetization of the ferromagnetic hard layer 141 with the magnitude of the magnetization of the reference magnetization layer 143. The thickness of the SAF layer 140L may be in a range from 5 nm to 30 nm, although lesser and greater thicknesses may also be used.

The nonmagnetic tunnel barrier material layer 146L may include a tunneling barrier material, which may be an electrically insulating material having a thickness that allows electron tunneling. For example, the nonmagnetic tunnel barrier material layer 146L may include magnesium oxide (MgO), aluminum oxide (Al₂O₃), aluminum nitride (AlN), aluminum oxynitride (AlON), hafnium oxide (HfO₂) or zirconium oxide (ZrO₂). Other suitable materials within the contemplated scope of disclosure may also be used. The thickness of the nonmagnetic tunnel barrier material layer 146L may be 0.7 nm to 1.3 nm, although lesser and greater thicknesses may also be used.

The free magnetization material layer 148L includes a ferromagnetic material having two stable magnetization directions that are parallel or antiparallel to the magnetization direction of the reference magnetization layer 143. The free magnetization material layer 148L includes a hard ferromagnetic material such as Co, CoFe, CoFeB, CoFeTa, NiFe, CoPt, CoFeNi, etc. Other suitable materials within the contemplated scope of disclosure may also be used. The thickness of the free magnetization material layer 148L may be in a range from 1 nm to 6 nm, although lesser and greater thicknesses may also be used.

The top electrode material layer 158L includes a top electrode material, which may include any nonmagnetic material that may be used for the bottom electrode material layer 126L. Thus, the top electrode material layer 158L includes a nonmagnetic metallic material containing a nonmagnetic metal element. Exemplary nonmagnetic metallic materials that may be used for the top electrode material layer 158L include, but are not limited to, TiN, TaN, WN, W, Cu, Al, Ti, Ta, Ru, Mo, Pt, an alloy thereof, and/or a combination thereof. Other suitable materials within the contemplated scope of disclosure may also be used. For example, the top electrode material layer 158L may include, and/or may consist essentially of, an elemental metal such as W, Cu, Ti, Ta, Ru, Mo, or Pt. The thickness of the top electrode material layer 158L may be in a range from 8 nm to 80 nm, such as from 16 nm to 40 nm, although lesser and greater thicknesses may also be used. In one embodiment, the top electrode material layer 158L may have a homogenous material composition throughout.

The material layers that are subsequently patterned into magnetic tunnel junction structures are collectively referred to as magnetic tunnel junction material layers (143, 146L, 148L), which include the reference magnetization layer 143, the nonmagnetic tunnel barrier material layer 146L, and the free magnetization material layer 148L. Generally, a layer stack including at least a bottom electrode material layer 126L, magnetic tunnel junction material layers (143, 146L, 148L), and a top electrode material layer 158L may be formed over the substrate 9. The top electrode material layer 158L comprises a metallic material containing a nonmagnetic metal element.

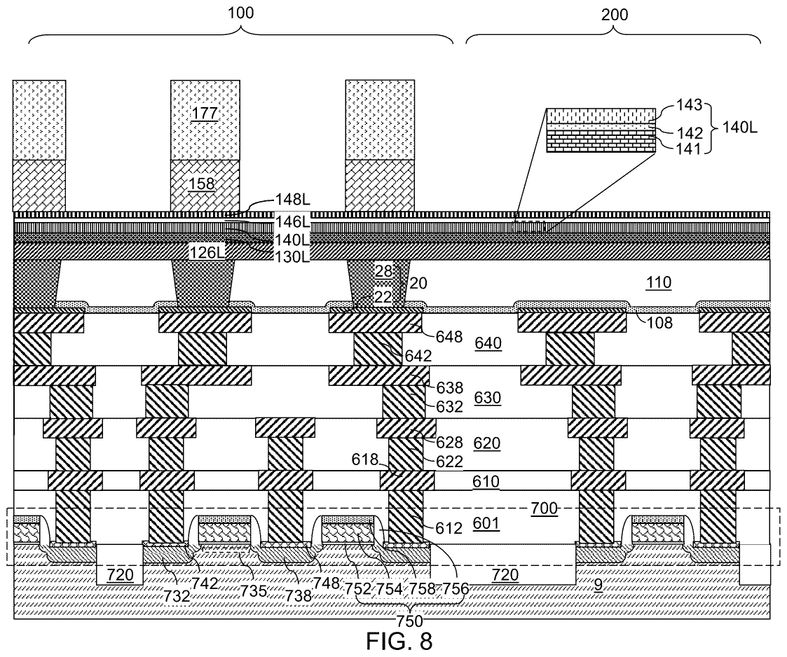

Referring to FIG. 8, a photoresist layer 177 may be applied over the top electrode material layer 158L, and may be lithographically patterned into an array discrete photoresist material portions in the memory array region 100. Each patterned portion of the photoresist layer 177 may overlie a respective one of the metallic via structures 20 (22, 28). The sidewall(s) of each patterned portion of the photoresist layer 177 may coincide with, may be laterally offset outward from, or may be laterally offset inward from, the periphery of a top surface of an underlying metallic via structure 20 (22, 28). The sidewall(s) of each patterned portion of the photoresist layer 177 may have a horizontal cross-sectional shape of a circle, an ellipse, a rectangle, a rounded rectangle, or of any generally curvilinear closed two-dimensional shape.

An anisotropic etch process may be performed to etch unmasked portions of the top electrode material layer 158L. In one embodiment, the topmost layer of the memory material layer stack (130L, 140L, 146L, 148L) may be used as an etch stop layer. Each patterned portion of the top electrode material layer 158L comprises a top electrode 158. A two-dimensional array of top electrodes 158 may be formed by the anisotropic etch process. Each top electrode 158 may be a patterned portion of the top electrode material layer 158L. In one embodiment, the top electrodes 158 comprise, and/or consist essentially of, a conductive metallic nitride material (such as TiN, TaN, or WN),

Generally, the top electrode material layer 158L may be patterned into a hard mask structure that includes at least one top electrode 158 such as a two-dimensional array of top electrodes 158. In one embodiment, the two-dimensional array of top electrodes 158 may be formed as a two-dimensional periodic array. In one embodiment, the two-dimensional periodic array of top electrodes 158 may be formed as a rectangular periodic array having a first pitch along a first horizontal direction and having a second pitch along a second horizontal direction that is perpendicular to the first horizontal direction. In one embodiment, the top electrodes 158 may include substantially vertical or tapered sidewalls that vertically extend from a bottom surface to a top surface of a respective top electrode 158. The photoresist layer 177 may be removed after the anisotropic etch process.

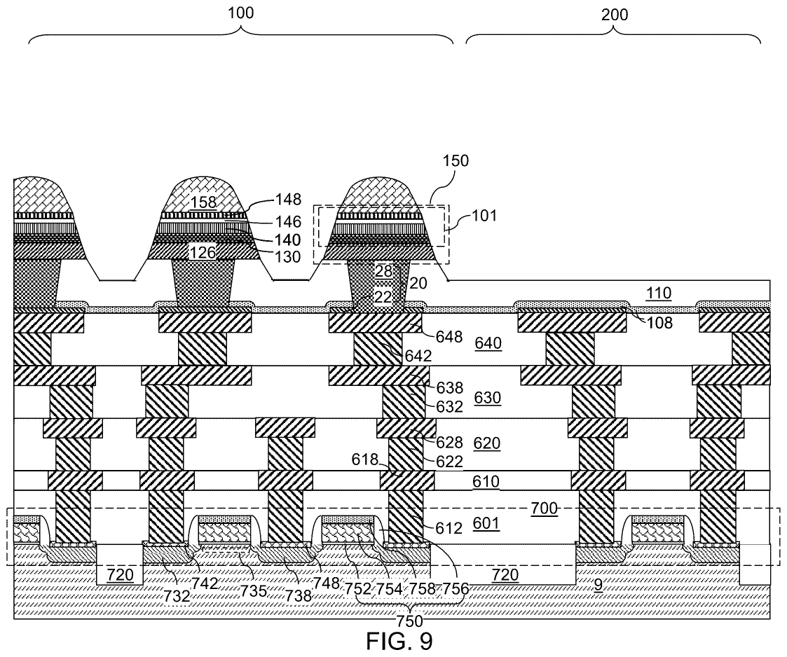

Referring to FIG. 9, the memory material layer stack (130L, 140L, 146L, 148L) and the bottom electrode material layer 126L may be patterned using a focused ion beam etch process. The array of top electrodes 158 may be used as a hard mask structure for the focused ion beam etch process. The focused ion beam etch process may use a focused beam of ions having energy in a range from 300 eV to 600 eV, although lesser and greater ion energies may also be used. The species of ions that may be used for the focused ion beam etch process include, but are not limited to, gallium, silicon, chromium, iron, cobalt, nickel, germanium, indium, tin, gold, and lead. In one embodiment, the focused ion beam etch process may include ions of a nonmagnetic element such as gallium. The focused ion beam may have a first angular spread in the propagation direction, which may be introduced, for example, by rastering. The first angular spread of the beam angle may be in a range from 0 degree to 30 degrees as measured from a vertical direction that is perpendicular to the bottom surfaces of the top electrodes 158.

The focused ion beam etch process sequentially etches unmasked portions of the various material layers of the memory material layer stack (130L, 140L, 146L, 148L) and the bottom electrode material layer 126L. The focused ion beam etch process patterns the memory material layer stack (130L, 140L, 146L, 148L) (which include the magnetic tunnel junction material layers (143, 146L, 148L) and the bottom electrode material layer 126L into a patterned structure that includes at least one pillar structure 150. Each pillar structure 150 comprises a bottom electrode 126 and a memory element 101. Each memory element 101 includes a magnetic tunnel junction structure (143, 146, 148) therein. In one embodiment, a two-dimensional array of top electrodes 158 may be used as an etch mask throughout the focused ion beam etch process. In this embodiment, portions of the memory material layer stack (130L, 140L, 146L, 148L) and the bottom electrode material layer 126L that are not masked by the two-dimensional array of top electrodes 158 may be etched by the focused ion beam etch process. The patterned structure may include a two-dimensional array of pillar structures 150.

A combination of a top electrode 158 and a pillar structure 150 constitutes a memory cell (158, 150). Thus, each memory cell (158, 150) includes a vertical stack including a top electrode 158, a memory element 101, and a bottom electrode 126. In one embodiment, each memory cell (158, 150) may be a magnetic tunnel junction (MTJ) memory cell. Each MTJ memory cell may include a bottom electrode 126, a magnetic tunnel junction structure (143, 146, 148), and a top electrode 158. Each memory element 101 comprises a vertical stack including a synthetic antiferromagnet structure 140, a tunnel barrier layer 146, and a free magnetization layer 148. Each memory element 101 may include an optional nonmagnetic metallic buffer layer and a magnetic tunnel junction structure (143, 146, 148).

Each magnetic tunnel junction structure (143, 146, 148) may include a reference magnetization layer 143 (which may be a component of a synthetic antiferromagnet (SAF) structure 140), a tunnel barrier layer 146, and a free magnetization layer 148. Generally, the ferromagnetic hard layer 141 and the antiferromagnetic coupling layer 142 in an SAF structure may be omitted, or may be replaced with another magnetic structure that stabilizes the direction of magnetization in the reference magnetization layer 143. A nonmagnetic metallic buffer layer 130 may be provided between the bottom electrode 126 and the magnetic tunnel junction structure (143, 146, 148). Each bottom electrode 126 is a patterned portion of the bottom electrode material layer 126L. Each SAF structure 140 may be a patterned portion of the SAF layer 140L. Each tunnel barrier layer 146 may be a patterned portion of the nonmagnetic tunnel barrier material layer 146L. Each free magnetization layer 148 may be a patterned portion of the free magnetization material layer 148L. The synthetic antiferromagnetic structure 140 may include a layer stack of a ferromagnetic hard layer 141, an antiferromagnetic coupling layer 142, and a reference magnetization layer 143. Generally, in embodiments in which each memory element 101 comprises a magnetic tunnel junction memory element, each memory element 101 may comprise a reference magnetization layer 143, a tunnel barrier layer 146 in contact with the reference magnetization layer 143, and a free magnetization layer 148 in contact with the tunnel barrier layer 146. Generally, the reference magnetization layer 143 includes a first ferromagnetic material, and the free magnetization layer 148 includes a second ferromagnetic material, which may be the same as, or may be different from, the first ferromagnetic material.

The pillar structures 150 may be tapered pillar structures having a respective tapered sidewall. Unmasked portions of the via-level dielectric layer 110 may be vertically recessed by the focused ion beam etch process. In an alternative embodiment, an ion milling process may be used in lieu of the focused ion beam etch process. The array of metallic via structures 20 (22, 28) may be located underneath the array of memory cells (158, 150), and may contact a bottom surface of a respective one of the bottom electrodes 126. This ion beam etch process forms shallow recess in the via-level dielectric layer 110 between the pillar structures 150. This feature provides the benefit of providing a tapered hard mask profile and a shallow recess depth, and applies magnetized inductively coupled plasma (MICP) for cleaning and/or oxidation of metallic ions. According to the present disclosure, a depth of the shallow recess is no more than 300 angstroms, shallower than a conventional recess.

The via-level dielectric layer 110 underlies the array of pillar structures 150. Portions of the via-level dielectric layer 110 that are not covered by the two-dimensional array of memory cells (158, 150) may be vertically recessed below the horizontal plane including the interfaces between the array of metallic via structures 20 (22, 28) and the array of memory cells (158, 150). The remaining portions of the via-level dielectric layer 110 may include a recessed horizontal top surface that is adjoined to bottom peripheries of tapered sidewalls of portions of the via-level dielectric layer 110 that underlie the array of memory cells (158, 150). As such, the via-level dielectric layer 110 comprises an array of mesa portions protruding upward from a planar portion of the via-level dielectric layer 110. The array of mesa portions of the via-level dielectric layer 110 contacts the array of pillar structures 150. In one embodiment, each mesa portion of the via-level dielectric layer 110 may contact an annular portion of a bottom surface of a respective pillar structure 150. Each mesa portion of the via-level dielectric layer 110 may have a tapered sidewall adjoined to a tapered sidewall of a pillar structure 150, which is herein referred to as a tapered pillar sidewall.

Generally, a top electrode 158 overlies a magnetic tunnel junction structure (143, 146, 148) in each memory cell (158, 150). The top electrodes 158 comprise a metallic material containing a nonmagnetic metal element. A metallic via structure 20 (22, 28) may be embedded within each mesa portion of the via-level dielectric layer 110, and may contact a center portion of the bottom surface of the pillar structure 150.

Optionally, a hard mask trim ion beam etch process may be performed. An ion beam having a second angular spread may be directed to the pillar structure 150 and the top electrodes 158. The second angular spread of the ion beam of the hard mask trim ion beam etch process may be less than the first angular spread of the ion beam of the focused ion beam etch process described above. Thus, a higher percentage of ions impinge on the top electrodes 158 than on the sidewalls of the pillar structures 150 during the hard mask trim ion beam etch process compared to the focused ion beam etch process.

While the present disclosure is described using an embodiment in which each memory element 101 comprises a respective magnetic tunnel junction, embodiments are expressly contemplated herein in which each magnetic tunnel junction is replaced with a different type of memory element such as a resistive random access memory (RRAM) cell, a ferroelectric memory cell, a phase change memory cell, a capacitor-based memory cell (such as a memory cell of a DRAM), or any other alternative memory cell. Thus, embodiments of the present disclosure may be used in conjunction with any type of memory cell including a bottom electrode and a top electrode and a memory element therebetween.

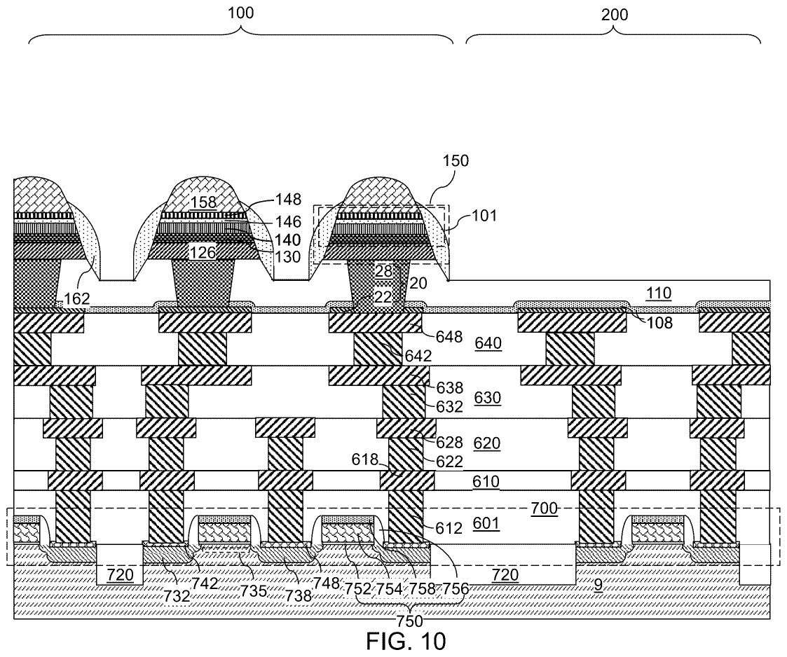

Referring to FIG. 10, a dielectric spacer material may be conformally deposited over the array of memory cells (158, 150). In one embodiment, the dielectric spacers 162 may include a diffusion barrier dielectric material such as silicon nitride. The dielectric spacer material may be deposited by a plasma-enhanced chemical vapor deposition process. The thickness of the dielectric spacer material may be in a range from 2 nm to 20 nm, such as from 4 nm to 10 nm, although lesser and greater thicknesses may also be used. An anisotropic etch process may be performed to remove horizontal portions of the dielectric spacer. Remaining portions of the dielectric spacer material comprise an array of dielectric spacers 162 that laterally surrounds the array of memory cells (158, 150). The maximum thickness of each dielectric spacer 162 may be in a range from 2 nm to 20 nm, such as from 4 nm to 10 nm, although lesser and greater thicknesses may also be used.

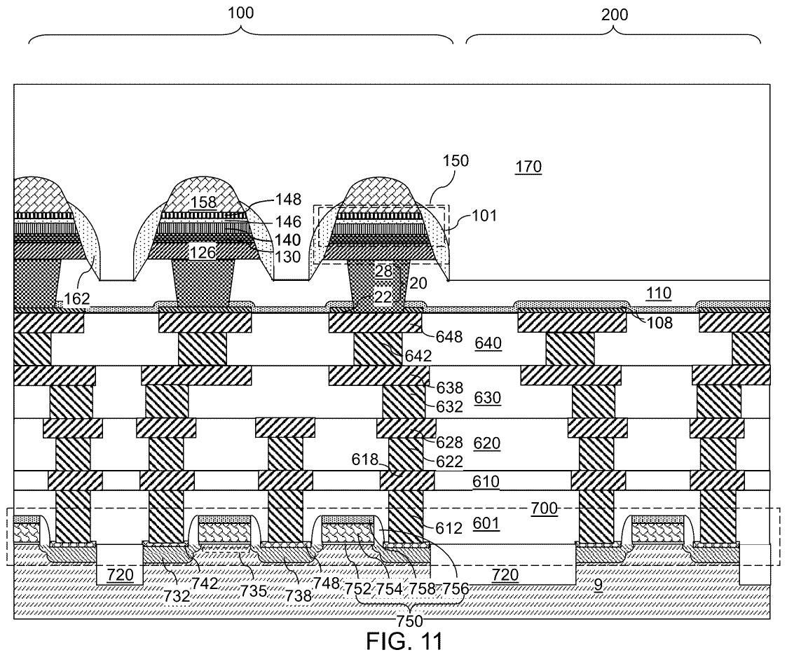

Referring to FIG. 11, memory-level dielectric layer 170 may be formed around, and over, the array of dielectric spacers 162 and the array of memory cells (158, 150). In one embodiment, the memory-level dielectric layer 170 laterally surrounds the dielectric spacers 162, and is laterally spaced from the pillar structures by the dielectric spacers 162. The memory-level dielectric layer 170 laterally surrounds, and embeds, each of the top electrodes 158. In one embodiment, the memory-level dielectric layer 170 includes a planarizable dielectric material such as undoped silicate glass or a doped silicate glass. The dielectric material of the memory-level dielectric layer 170 may be deposited by a conformal deposition process (such as a chemical vapor deposition process) or a self-planarizing deposition process (such as spin coating). The memory-level dielectric layer 170 may be formed with a planar top surface (for example, as formed by spin-coating), or the memory-level dielectric layer 170 may be planarized by a planarization process (such as a chemical mechanical planarization process) to provide a planar top surface. The minimum vertical distance between the planar top surface of the memory-level dielectric layer 170 and the top electrodes 158 may be in a range from 30 nm to 300 nm, although lesser and greater minimum vertical distances may also be used.

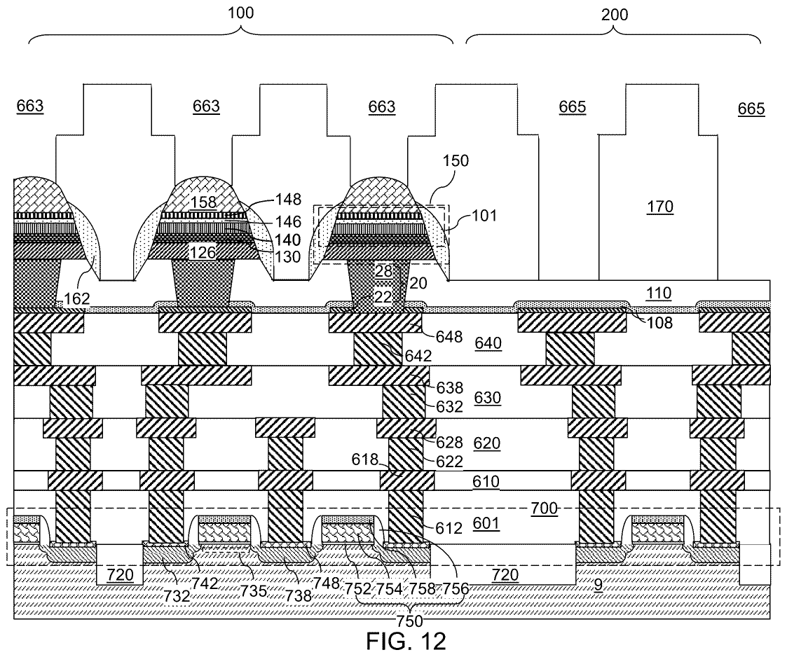

Referring to FIG. 12, at least one lithographic patterning step and at least one anisotropic etch process may be used to form memory-level interconnect cavities (663,665) in the memory-level dielectric layer 170. For example, a first photoresist layer (not shown) may be applied over the memory-level dielectric layer 170 and may be lithographically patterned to form an array of discrete openings in the first photoresist layer. A first anisotropic etch process may be performed to form via cavities in the memory-level dielectric layer 170. After removal of the first photoresist layer, a second photoresist layer (not shown) may be applied over the memory-level dielectric layer 170 and may be lithographically patterned to form line-shaped openings in the second photoresist layer. A second anisotropic etch process may be performed to form line cavities in the memory-level dielectric layer 170. The second photoresist layer may be subsequently removed.

First memory-level interconnect cavities 663 may be formed in the memory array region 100, and second memory-level interconnect cavities 665 may be formed in the peripheral region 200. In on embodiment, the memory-level interconnect cavities (663, 665) may be formed as integrated line and via cavities. In this embodiment, each integrated line and via cavity may include a line cavity that is located within an upper portion of the memory-level dielectric layer 170, and at least one via cavity adjoined to a bottom portion of the line cavity and vertically extends through an upper portion of the memory-level dielectric layer 170 and down to a top surface of an underlying metallic structure. Specifically, a convex top surface of a top electrode 158 may be physically exposed at the bottom of each first memory-level interconnect cavity 663. The second memory-level interconnect cavities 665 vertically extend through the memory-level dielectric layer 170, the via-level dielectric layer 110, and the dielectric cap layer 108, and a top surface of a metal line structure (such as a fourth metal line structure 648) may be physically exposed at the bottom of each second memory-level interconnect cavity 665. Generally, the first memory-level interconnect cavities 663 may vertically extend between the top surface of the memory-level dielectric layer 170 and a top surface of a respective one of the top electrodes 158, and the second memory-level interconnect cavities 665 may vertically extend between the top surface of the memory-level dielectric layer 170 and a top surface of a respective underlying metal interconnect structure.

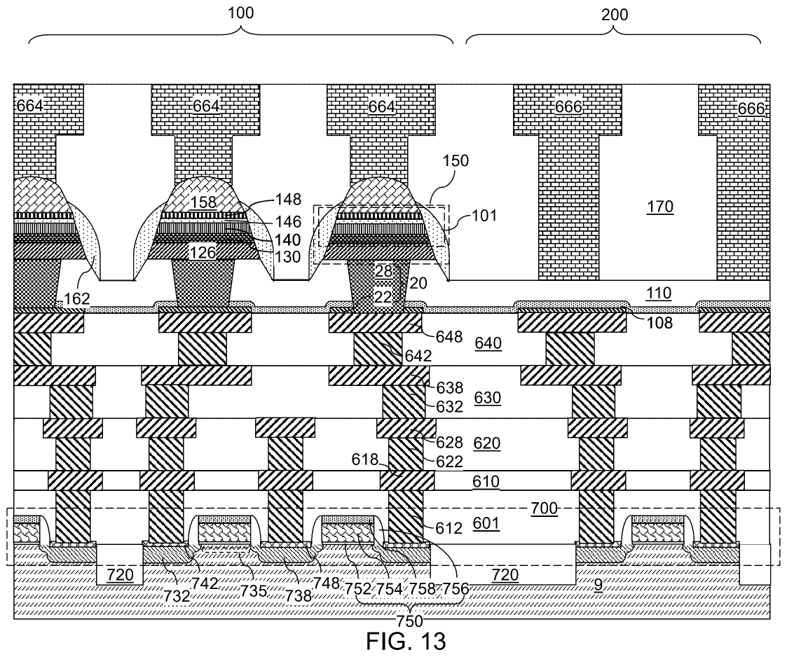

Referring to FIG. 13, at least one metallic material may be deposited in the memory-level interconnect cavities (663, 665). The at least one metallic material is herein referred to as memory-level metallic material. In one embodiment, a metallic barrier material layer (such as a TiN, layer, TaN layer, and/or a WN layer) and a metallic fill material (such as W, Cu, Co, Ru, Mo, or an intermetallic alloy) may be deposited in the memory-level interconnect cavities (663, 665) and over the memory-level dielectric layer 170.

A planarization process such as a chemical mechanical planarization process may be performed to remove the memory-level metallic material from above the memory-level dielectric layer 170. The chemical mechanical planarization process may remove the memory-level metallic material from above the horizontal plane including the top surface of the memory-level dielectric layer 170. Remaining portions of the memory-level metallic material filling the memory-level interconnect cavities (663, 665) comprise memory-level metal interconnect structures (664, 666). In one embodiment, the memory-level metal interconnect structures (664, 666) may include integrated line and via structures that includes a respective metal line and a respective set of at least one metal via structures. The metal lines of the memory-level metal interconnect structures (664, 666) may have top surfaces within the horizontal plane including the top surface of the memory-level dielectric layer 170.

The memory-level metal interconnect structures (664, 666) comprise first memory-level metal interconnect structures 664 and second memory-level metal interconnect structures 666. The first memory-level metal interconnect structures 664 may vertically extend through the memory-level dielectric layer 170, and may include a respective contact via structure that contacts a respective one of the top electrodes 158. The second memory-level metal interconnect structures 666 may vertically extend through the memory-level dielectric layer 170, and may include a respective via portion that contacts a respective one of the underlying metal interconnect structures. Generally, for each memory cell (158, 150) within a two-dimensional array of memory cells (158, 150), a contact via structure (which may comprise a portion of a first memory-level metal interconnect structure 664) contacts a convex top surface of a top electrode 158. Each contact via structure that contacts a top electrode 158 may extend through the memory-level dielectric layer 170, and may contact a convex top surface of the top electrode 158.

Additional metal interconnect structures (not shown) may be formed above the memory level, which vertically extend from the bottom surface of the dielectric cap layer 108 to the top surface of the memory-level dielectric layer. The additional metal interconnect structures may be formed within additional dielectric material layers (not shown). The memory-level metal interconnect structures (664, 666) and the additional metal interconnect structures may be used to electrically connect the top electrodes 158 of the memory cells (158, 150) to a respective electrical node of the CMOS circuitry 700.

Generally, a memory cell (158, 150) may be formed on a metal via fill structure 28. The memory cell (158, 150) comprises a bottom electrode 126, a memory element (such as a magnetic tunnel junction structure (143, 146, 148)), and a top electrode 158. The bottom electrode 126 is formed directly on a top surface of the metal via fill structure 28.

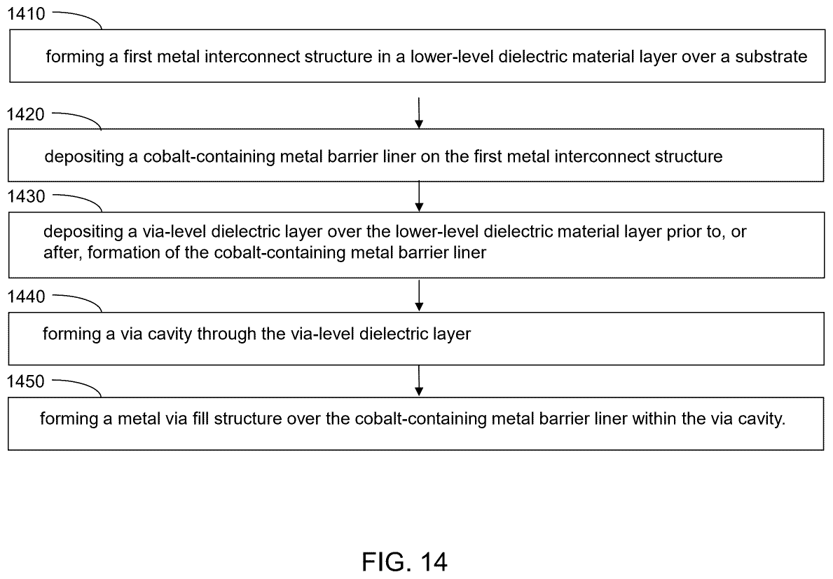

Referring to FIG. 14, a first flowchart illustrates a first sequence of processing steps for manufacturing a device structure of the present disclosure.

Referring to step 1410 and FIGS. 1 and 2A, a first metal interconnect structure (such as a fourth metal line structure 648) may be formed in a lower-level dielectric material layer (such as the fourth line-and-via-level dielectric material layer 640) over a substrate 9.

Referring to step 1420 and FIGS. 2B, 3C, and 4C, a cobalt-containing metal barrier liner 22 may be deposited on the first metal interconnect structure (such as a fourth metal line structure 648).

Referring to step 1430 and FIGS. 2C, 3A, and 4A, a via-level dielectric layer 110 may be deposited over the lower-level dielectric material layer (such as the fourth line-and-via-level dielectric material layer 640) prior to, or after, formation of the cobalt-containing metal barrier liner 22.

Referring to step 1440 and FIGS. 2D, 3B, and 4B, a via cavity 119 may be formed through the via-level dielectric layer 110.

Referring to step 1450 and FIGS. 2E, 2F, 3D, 3E, 4D, 4E, 4F, 5A, 5B, and 6 13, a metal via fill structure 28 may be formed over the cobalt-containing metal barrier liner 22 within the via cavity 119.

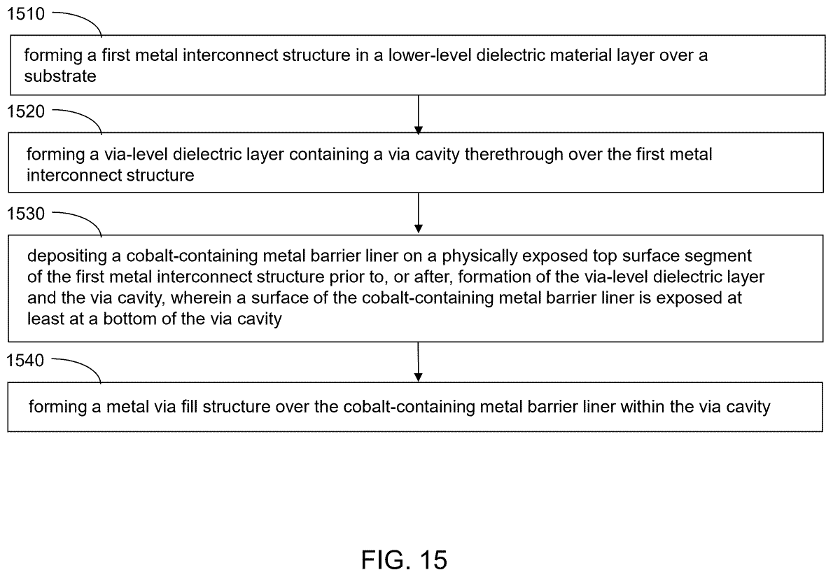

FIG. 15 is a second flowchart that illustrates a second sequence of processing steps for manufacturing a device structure of the present disclosure.

Referring to step 1510 and FIGS. 1 and 2A, a first metal interconnect structure (such as a fourth metal line structure 648) may be formed in a lower-level dielectric material layer (such as the fourth line-and-via-level dielectric material layer 640) over a substrate 9.

Referring to step 1520 and FIGS. 2C, 2D, 3A, 3B, 4A, and 4B, a via-level dielectric layer 110 containing a via cavity 119 therethrough may be formed over the first metal interconnect structure (such as a fourth metal line structure 648).

Referring to step 1530 and FIGS. 2B, 3C, and 4C, a cobalt-containing metal barrier liner 22 may be formed on a physically exposed top surface segment of the first metal interconnect structure (such as a fourth metal line structure 648) prior to, or after, formation of the via-level dielectric layer 110 and the via cavity 119. A surface of the cobalt-containing metal barrier liner 22 is exposed at least at a bottom of the via cavity 119.

Referring to step 1540 and FIGS. 2E, 2F, 3D, 3E, 4D, 4E, 4F, 5A, 5B, and 6 13, a metal via fill structure 28 is formed over the cobalt-containing metal barrier liner 22 within the via cavity 119.

Referring to all drawings and according to various embodiments of the present disclosure, a device structure is provided, which comprises: a first metal interconnect structure (such as a fourth metal line structure 648) located in a lower-level dielectric material layer (such as the fourth line-and-via-level dielectric material layer 640) that overlies a substrate 9; a metal via fill structure 28 located within a via-level dielectric layer 110 that overlies the first metal interconnect structure (such as a fourth metal line structure 648); and a cobalt-containing metal barrier liner 22 located on a top surface of the first metal interconnect structure (such as a fourth metal line structure 648) and interposed between the first metal interconnect structure (such as a fourth metal line structure 648) and the metal via fill structure 28.

In one embodiment, the device structure comprises a memory cell 101 located on the metal via fill structure 28, wherein the memory cell comprises a bottom electrode 126, a memory element (such as a magnetic tunnel junction structure (143, 146, 148)), and a top electrode 158, and the bottom electrode 126 contacts a top surface of the metal via fill structure 28.

In one embodiment, the cobalt-containing metal barrier liner 22 comprise an alternating stack of cobalt layers 22C and tungsten layers 22W. In one embodiment, the cobalt-containing metal barrier liner 22 consists essentially of cobalt. In one embodiment, a top surface of the first metal interconnect structure (such as a fourth metal line structure 648) has a first lateral extent LE1 along a first horizontal direction hd1; and a bottom surface of the cobalt-containing metal barrier liner 22 has a second lateral extent LE2 that is greater than the first lateral extent LE1 along the first horizontal direction hd1.

Embodiments of the present disclosure provide a device structure that integrates a cobalt-containing metal barrier liner 22 within a metallic via structure 20 to enhance electrical connectivity, electromigration resistance, and diffusion barrier effectiveness. The cobalt-containing metal barrier liner 22 is located between a first metal interconnect structure and a metal via fill structure 28, forming a low-resistance interconnect pathway that reduces contact resistance and mitigates metal diffusion.

In an embodiment, the cobalt-containing metal barrier liner 22 comprises a multilayer stack of cobalt layers 22C and tungsten layers 22W, enhancing barrier integrity while maintaining high electrical conductivity. Alternatively, in an embodiment, the cobalt-containing metal barrier liner 22 consists of a single cobalt layer 22C, which may be selectively deposited via atomic layer deposition or chemical vapor deposition to ensure precise placement and minimal material consumption. In an embodiment, the metal via fill structure 28 is deposited within a via cavity 119, contacting the cobalt-containing metal barrier liner 22. In an embodiment, the via cavity 119 is formed within a via-level dielectric layer 110 and is created via an anisotropic etch process, ensuring precise via geometry and reliable electrical coupling.

By integrating a cobalt-containing metal barrier liner 22 within the metallic via structure 20, the present disclosure addresses challenges associated with electromigration, high resistance, and interconnect reliability in advanced semiconductor devices. The cobalt-containing metal barrier liner 22 of the present disclosure may reduce resistance-capacitance delay, may mitigate against copper diffusion, may enhance interconnect reliability, and may provide continued device scaling. Embodiments of the present disclosure provides a scalable and high-performance solution for next-generation semiconductor manufacturing.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming a first metal interconnect structure in a lower-level dielectric material layer over a substrate;
depositing a cobalt-containing metal barrier liner on the first metal interconnect structure;
depositing a via-level dielectric layer over the lower-level dielectric material layer prior to, or after, formation of the cobalt-containing metal barrier liner;
forming a via cavity through the via-level dielectric layer; and
forming a metal via fill structure over the cobalt-containing metal barrier liner within the via cavity.

2. The method of claim 1, further comprising forming a memory cell on the metal via fill structure, wherein the memory cell comprises a bottom electrode, a memory element, and a top electrode, and the bottom electrode is formed directly on a top surface of the metal via fill structure.

3. The method of claim 1, wherein the cobalt-containing metal barrier liner is formed by selective deposition of at least one metal comprising cobalt on a physically exposed top surface of the first metal interconnect structure while suppressing growth of the at least one metal from dielectric surfaces.

4. The method of claim 3, wherein:
the at least one metal comprises a combination of cobalt and tungsten; and
the cobalt-containing metal barrier liner is formed by alternately performing selective cobalt deposition steps and selective tungsten deposition steps.

5. The method of claim 4, wherein:
each of the selective cobalt deposition steps comprises a respective first area-selective atomic layer deposition process using a cobalt-containing precursor gas; and
each of the selective tungsten deposition steps comprises a respective second area-selective atomic layer deposition process using a tungsten-containing precursor gas.

6. The method of claim 3, wherein:
the at least one metal consists of cobalt; and
the cobalt-containing metal barrier liner is formed by performing a single selective cobalt deposition process.

7. The method of claim 1, wherein:
the cobalt-containing metal barrier liner is formed on a physically exposed top surface of the first metal interconnect structure; and
the via-level dielectric layer is formed over the cobalt-containing metal barrier liner.

8. The method of claim 7, wherein:
the via cavity is formed by performing an anisotropic etch process such that a top surface segment of the cobalt-containing metal barrier liner is exposed underneath the via cavity; and
the metal via fill structure is formed directly on the top surface segment of the cobalt-containing metal barrier liner.

9. The method of claim 1, wherein:
the via-level dielectric layer is formed on an entirety of a top surface of the first metal interconnect structure;
the via cavity is formed by performing an anisotropic etch process such that a segment of the top surface of the first metal interconnect structure is physically exposed; and
the cobalt-containing metal barrier liner is formed on the physically exposed segment of the top surface of the first metal interconnect structure.

10. The method of claim 9, wherein the cobalt-containing metal barrier liner is formed by a non-selective deposition of at least one metal comprising cobalt on the physically exposed segment of the top surface of the first metal interconnect structure and over a sidewall and a top surface of the via-level dielectric layer.

11. A method of forming a device structure, comprising:
forming a first metal interconnect structure in a lower-level dielectric material layer over a substrate;
forming a via-level dielectric layer containing a via cavity therethrough over the first metal interconnect structure;
depositing a cobalt-containing metal barrier liner on a physically exposed top surface segment of the first metal interconnect structure prior to, or after, formation of the via-level dielectric layer and the via cavity, wherein a surface of the cobalt-containing metal barrier liner is exposed at least at a bottom of the via cavity; and
forming a metal via fill structure over the cobalt-containing metal barrier liner within the via cavity.

12. The method of claim 11, wherein the cobalt-containing metal barrier liner is formed by performing an alternating sequence of cobalt deposition steps and tungsten deposition steps.

13. The method of claim 12, wherein the cobalt-containing metal barrier liner is formed by performing a cobalt deposition process that deposit a cobalt layer consisting essentially of cobalt.

14. The method of claim 11, wherein the cobalt-containing metal barrier liner is formed by performing a selective metal deposition process that grows at least one metal comprising cobalt from the physically exposed top surface segment of the first metal interconnect structure while suppressing growth of the at least one metal from dielectric surfaces.

15. The method of claim 11, further comprising forming a memory cell on the metal via fill structure, wherein the memory cell comprises a bottom electrode, a memory element, and a top electrode, and the bottom electrode is formed directly on a top surface of the metal via fill structure.

16. A device structure comprising:
a first metal interconnect structure located in a lower-level dielectric material layer that overlies a substrate;
a metal via fill structure located within a via-level dielectric layer that overlies the first metal interconnect structure; and
a cobalt-containing metal barrier liner located on a top surface of the first metal interconnect structure and interposed between the first metal interconnect structure and the metal via fill structure.

17. The device structure of claim 16, further comprising a memory cell located on the metal via fill structure, wherein the memory cell comprises a bottom electrode, a memory element, and a top electrode, and the bottom electrode contacts a top surface of the metal via fill structure.

18. The device structure of claim 16, wherein the cobalt-containing metal barrier liner comprise an alternating stack of cobalt layers and tungsten layers.

19. The device structure of claim 16, wherein the cobalt-containing metal barrier liner consists essentially of cobalt.

20. The device structure of claim 16, wherein:
a top surface of the first metal interconnect structure has a first lateral extent along a first horizontal direction; and
a bottom surface of the cobalt-containing metal barrier liner has a second lateral extent that is greater than the first lateral extent along the first horizontal direction.
